(19) United States
(12) Patent Application Publication
(10) Pub. No.: US 2025/0280593 A1
(43) Pub. Date: Sep. 4, 2025

(54) SEMICONDUCTOR DEVICE

(71) Applicant: FUJI ELECTRIC CO., LTD., Kawasaki-shi (JP)

(72) Inventor: Keisuke SHIBA, Matsumoto-city (JP)

(73) Assignee: FUJI ELECTRIC CO., LTD., Kawasaki-shi (JP)

(21) Appl. No.: 19/039,982

(22) Filed: Jan. 29, 2025

(30) Foreign Application Priority Data
Mar. 1, 2024 (JP) 2024-031746

(51) Int. Cl. H10D 84/00; H01J 37/317; H01L 21/265; H10D 8/60; H10D 30/66; H10D 62/10; H10D 62/53

(52) U.S. Cl. CPC H10D 84/146; H01J 37/3171; H01L 21/26513; H10D 8/60; H10D 30/665; H10D 30/668; H10D 62/106; H10D 62/53

(57) ABSTRACT

A semiconductor device, comprising: a semiconductor substrate, a parallel pn layer formed in the semiconductor substrate; first semiconductor regions selectively provided in the semiconductor substrate and in contact with the parallel pn layer; second semiconductor regions selectively provided in the semiconductor substrate; gate electrodes respectively provided at positions facing the semiconductor substrate across gate insulating films; first and second electrodes respectively provided at first and second main surfaces of the semiconductor substrate; and conductive films selectively provided between the first main surface of the semiconductor substrate and the first electrode, each conductive film being in contact with the first electrode and first-conductivity-type column regions. The conductive films and the first-conductivity-type column regions form Schottky junctions therebetween, configuring a Schottky barrier diode. The parallel pn layer has a first low carrier lifetime region formed at depth positions respectively directly beneath the first semiconductor regions.

### CROSS REFERENCE TO RELATED APPLICATIONS

This application is based upon and claims the benefit of priority of the prior Japanese Patent Application No. 2024-031746, filed on Mar. 1, 2024, the entire contents of which are incorporated herein by reference.

### BACKGROUND OF THE INVENTION

### 1. Field of the Invention

Embodiments of the invention relate to a semiconductor device.

### 2. Description of the Related Art

Conventionally, structures are known that reduce size and improve reverse recovery characteristics of a normal MOSFET, which has a drift layer configured by only an n⁻-type region or a SJ-MOSFET with a super junction (SJ) structure in which the drift layer is configured by a parallel pn layer having n-type column regions and p-type column regions, such structures reduce the size and improve the reverse recovery characteristics by disposing a Schottky barrier diode (SBD) on a single semiconductor substrate together with the MOSFET or by locally shortening carrier lifetime in the semiconductor substrate (for example, refer to Japanese Laid-Open Patent Publication No. 2022-164914, Japanese Laid-Open Patent Publication No. 2021-027138, Japanese Patent No. 6732359, Japanese Laid-Open Patent Publication No. 2009-054961, and Japanese Laid-Open Patent Publication No. 2015-018913.

### SUMMARY OF THE INVENTION

According to an embodiment of the present invention, a semiconductor device includes: a semiconductor substrate having an active region and a termination region that surrounds a periphery of the active region in a plan view of the semiconductor device, the semiconductor substrate further having a first main surface and a second main surface opposite to each other; a parallel pn layer formed in the semiconductor substrate, the parallel pn layer including a plurality of first-conductivity-type column regions of a first conductivity type and a plurality of second-conductivity-type column regions of a second conductivity that are disposed in the active region and repeatedly alternating with each other in a first direction that is parallel to the first main surface of the semiconductor substrate; a plurality of first semiconductor regions of the second conductivity type, selectively provided in the semiconductor substrate and in contact with the parallel pn layer; a plurality of second semiconductor regions of the first conductivity type, selectively provided in the semiconductor substrate, at the first main surface thereof, each of the plurality of second semiconductor regions being in contact with one of the plurality of first semiconductor regions; a plurality of gate insulating films selectively provided at the first main surface of the semiconductor substrate, in the active region; a plurality of gate electrodes respectively provided at positions facing the semiconductor substrate across the plurality of gate insulating films, in the active region; a first electrode provided at the first main surface of the semiconductor substrate, in contact with the plurality of second semiconductor regions; a second electrode provided at the second main surface of the semiconductor substrate; and a plurality of conductive films selectively provided between the first main surface of the semiconductor substrate and the first electrode, each of the plurality of conductive films being in contact with the first electrode and the plurality of first-conductivity-type column regions. The plurality of conductive films and the plurality of first-conductivity-type column regions form a plurality of Schottky junctions therebetween, configuring a Schottky barrier diode; and the parallel pn layer has a first low carrier lifetime region, in which a first carrier lifetime killer is introduced, formed at depth positions respectively directly beneath the plurality of first semiconductor regions, across an entire area of the active region.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a plan view depicting a layout when a semiconductor device according to a first embodiment is viewed from a front surface of a semiconductor substrate thereof.

FIG. 2 is a plan view depicting an enlarged view of a portion of an active region in FIG. 1.

FIG. 3 is a cross-sectional view of a structure along cutting line A-A′ in FIG. 2.

FIG. 4 is a plan view depicting a layout when a portion of the active region of a semiconductor device according to a second embodiment is viewed from the front surface of the semiconductor substrate.

FIG. 5 is a cross-sectional view of the structure along cutting line B-B′ in FIG. 4.

FIG. 6 is a cross-sectional view of the structure along cutting line C-C′ in FIG. 4.

FIG. 7 is a plan view depicting a layout when a portion of the active region of a semiconductor device according to a third embodiment is viewed from the front surface of the semiconductor substrate.

FIG. 8 is a cross-sectional view of the structure along cutting line D1-D1′ in FIG. 7.

FIG. 9 is a cross-sectional view of the structure along cutting line D2-D2′ in FIG. 7.

FIG. 10 is a cross-sectional view of the structure along cutting line E-E′ in FIG. 7.

FIG. 11 is a cross-sectional view depicting a structure of a semiconductor device according to a fourth embodiment.

FIG. 12 is a cross-sectional view depicting another example of the structure of the semiconductor device according to the fourth embodiment.

FIG. 13 is a cross-sectional view depicting another example of the structure of the semiconductor device according to the fourth embodiment.

FIG. 14 is a plan view depicting a layout when a portion of the active region of a semiconductor device according to a fifth embodiment is viewed from the front surface of the semiconductor substrate.

FIG. 15A is a cross-sectional view of the structure along cutting line F1-F1′ in FIG. 14.

FIG. 15B is a cross-sectional view of the structure along cutting line F2-F2′ in FIG. 14.

FIG. 16 is a cross-sectional view of the structure along cutting line G-G′ in FIG. 14.

FIG. 17 is a cross-sectional view of the structure along cutting line H-H′ in FIG. 14.

FIG. 18 is a plan view depicting a layout when a semiconductor device according to a sixth embodiment is viewed from the front surface of the semiconductor substrate.

FIG. 19 is a plan view depicting another example of the layout when the semiconductor device according to the sixth embodiment is viewed from the front surface of the semiconductor substrate.

FIG. 20 is a cross-sectional view of the structure along cutting line I-I′ in FIG. 18.

FIG. 21 is a cross-sectional view of the structure along cutting line J-J′ in FIG. 18.

FIG. 22 is a cross-sectional view of the structure along cutting line K-K′ in FIG. 18.

FIG. 23 is a cross-sectional view of another example of the structure along cutting line I-I′ in FIG. 18.

FIG. 24 is a cross-sectional view of another example of the structure along cutting line J-J′ in FIG. 18.

FIG. 25 is a cross-sectional view of another example of the structure along cutting line K-K′ in FIG. 18.

FIG. 26 is a cross-sectional view of the structure along cutting line L-L′ in FIG. 18.

FIG. 27 is a cross-sectional view of the structure along cutting line M-M′ in FIG. 18.

FIG. 28 is a cross-sectional view of another example of the structure along cutting line N-N′ in FIG. 18.

FIG. 29 is a cross-sectional view of another example of the structure along cutting line L-L′ in FIG. 18.

FIG. 30 is a cross-sectional view of another example of the structure along cutting line M-M′ in FIG. 18.

FIG. 31 is a cross-sectional view of the structure along cutting line N-N′ in FIG. 18.

FIG. 32 is a cross-sectional view depicting a structure of a semiconductor device according to an eighth embodiment.

FIG. 33 is a cross-sectional view depicting another example of the structure of the semiconductor device according to the eighth embodiment.

FIG. 34 is a plan view depicting a layout when a semiconductor device of a reference example is viewed from a front surface of a semiconductor substrate thereof.

FIG. 35 is a cross-sectional view of a structure along cutting line AA-AA′ in FIG. 34.

### DETAILED DESCRIPTION OF THE INVENTION

First, problems associated with the conventional techniques are discussed. In a conventional SJ-MOSFET, reverse recovery characteristics of parasitic pn junction diodes (body diodes) exhibit hard recovery, adversely affecting switching characteristics of the SJ-MOSFET and operation of peripheral components electrically connected to the SJ-MOSFET.

Embodiments of a semiconductor device according to the present invention are described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. In the description of the embodiments below and the accompanying drawings, main portions that are identical are given the same reference numbers and are not repeatedly described.

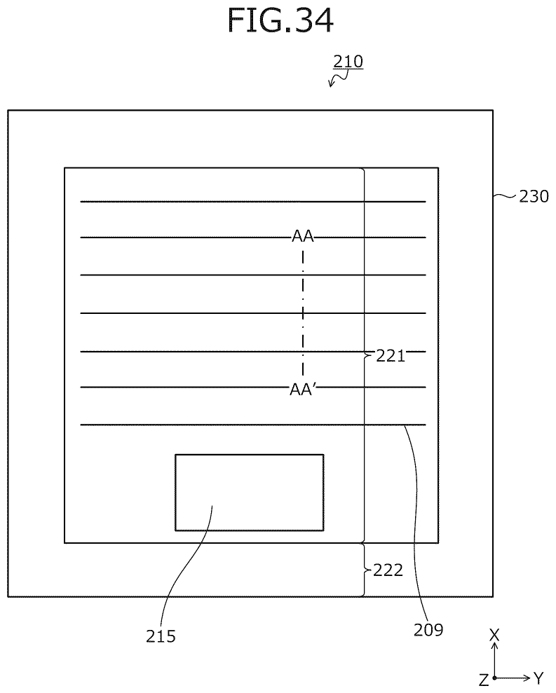

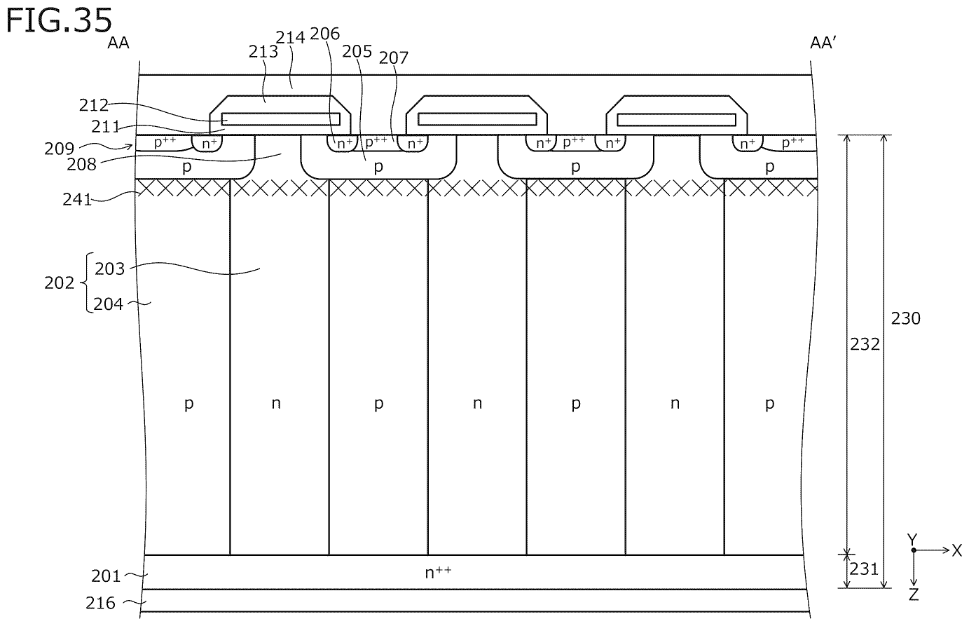

Problems associated with a semiconductor device of a reference example are discussed. FIG. 34 is a plan view depicting a layout when the semiconductor device of the reference example is viewed from a front surface of a semiconductor substrate thereof. FIG. 35 is a cross-sectional view of a structure along cutting line AA-AA′ in FIG. 34. A semiconductor device 210 of the reference example depicted in FIGS. 34 and 35 is a metal oxide semiconductor field effect transistor (MOSFET) having insulated gates formed by a three-layer metal-oxide-semiconductor structure and further having a super junction (SJ) structure in which a drift layer is constituted by a parallel pn layer 202, in an active region 221 of a semiconductor substrate (semiconductor chip) 230 that contains silicon carbide (SiC) as a semiconductor material.

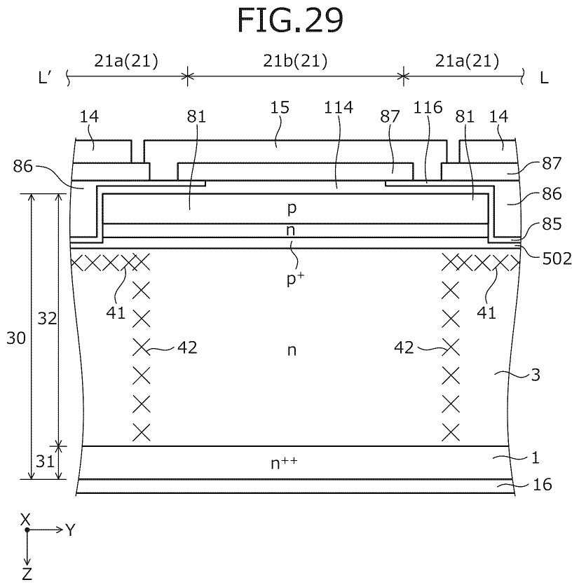

The active region 221 has a substantially rectangular shape in a plan view and is disposed in substantially a center of the semiconductor substrate 230. In the active region 221, multiple cells (functional units of a device) 209 each having a same structure (herein, planar gate structure: insulated gate structure) of the MOSFET are disposed adjacently to each other in a first direction X, which is parallel to a front surface of the semiconductor substrate 230. Each of the cells 209 extends linearly in a stripe-like shape in a second direction Y, which is parallel to the front surface of the semiconductor substrate 230 and orthogonal to the first direction X. In the active region 221, a source pad (a source electrode 214, not depicted in FIG. 29) and a gate pad 215 are disposed on the front surface of the semiconductor substrate 230. An edge termination region 222 is a region between the active region 221 and a chip end (end of the semiconductor substrate 230) and surrounds a periphery of the active region 221.

In the parallel pn layer 202, n-type column regions 203 and p-type column regions 204 are disposed adjacently, repeatedly alternating with each other in the first direction X. The n-type column regions 203 and the p-type column regions 204 extend linearly in the second direction Y. The cells 209 are configured by p-type base regions 205, n⁺-type source regions 206, p⁺⁺-type contact regions 207, junction FET (JFET) regions 208, gate insulating films 211, and gate electrodes 212; the cells 209 extend linearly in the second direction Y. The source electrode 214 is in contact with the n⁺-type source regions 206 and the p⁺⁺-type contact regions 207 via contact holes of an interlayer insulating film 213. At a back surface of the semiconductor substrate 230, an n⁺⁺-drain region 201 and a drain electrode 216 are provided.

In the semiconductor device 210 of the reference example, when voltage that is positive with respect to the source electrode 214 is applied to the drain electrode 216 and current applied to the gate electrodes 212 is less than a gate threshold voltage, pn junctions between the p-type base regions 205, the p-type column regions 204, and the n-type column regions 203 are reverse biased and thus, the SJ-MOSFET remains in an off-state. A depletion layer spreads vertically (toward the source electrode 214 and toward the drain electrode 216) from pn junctions between the p-type base regions 205 and the n-type column regions 203, and a depletion layer spreads outwardly (toward the chip end) from pn junctions between the p-type column regions 204 and the n-type column regions 203. A portion of the depletion layer spreading outwardly across the edge termination region 222 sustains a predetermined breakdown voltage based on a breakdown field strength of the semiconductor material (herein, SiC) and a width of the depletion layer.

Further, in the semiconductor device 210 of the reference example, only parasitic pn junction diodes (body diodes) formed by the pn junctions between the p-type base regions 205, the p-type column regions 204, and the n-type column regions 203 are built-in. During a period when the SJ-MOSFET transitions from on to off, the body diodes conduct, and electrons and holes are injected into and stored in the p-type column regions 204 and the n-type column regions 203 of the parallel pn layer 202, respectively. From this state, when the SJ-MOSFET is in the off-state (reverse recovery state of the body diodes), carriers (electrons and holes) in the parallel pn layer 202 are discharged to the drain electrode 216 and the source electrode 214, current (reverse recovery current of the body diodes) flows in a reverse direction to the pn junctions between the p-type base regions 205 and the n-type column regions 203, and the carriers in the parallel pn layer 202 are reduced.

While the carriers in the parallel pn layer 202 are reduced, the carriers in the parallel pn layer 202 are discharged to the drain electrode 216 and the source electrode 214, whereby a depletion layer spreads in a vertical direction from the pn junctions between the p-type base regions 205 and the n-type column regions 203 and reverse voltage applied to the pn junctions increases. Reverse voltage applied to the pn junctions between the p-type column regions 204 and the n-type column regions 203 also increases and thus, recombination of carriers near the pn junctions between the p-type column regions 204 and the n-type column regions 203 progresses and the carriers disappear from the parallel pn layer 202 in a short period of time. This phenomenon appears in the switching operation of the SJ-MOSFET as a sudden change in the reverse recovery current of the body diode of the SJ-MOSFET. The number of carriers that disappear from the parallel pn layer 202 per unit time varies depending on the design of the parallel pn layer 202.

In general, a greater is an area of the pn junctions between the p-type column regions 204 and the n-type column regions 203, the greater is the number of carriers that are stored in the parallel pn layer 202 when the SJ-MOSFET is on and thus, a peak value (maximum current value) of the reverse recovery current of the body diodes increases and as the rate of change over time (decreasing rate) di/dt from the peak value increases, the change in the reverse recovery current of the body diode becomes steeper (hard recovery). On the other hand, as the area of the pn junctions between the p-type column regions 204 and the n-type column regions 203 decreases, the number of carriers stored in the parallel pn layer 202 when the SJ-MOSFET is on decreases and thus, the peak value of the reverse recovery current of the body diodes decreases and the rate of change over time di/dt from the peak value decreases, whereby changes in the reverse recovery current of the body diodes become gradual (soft recovery).

When the change in the reverse recovery current of the body diodes is steep, switching characteristics of the SJ-MOSFET and operation of peripheral components electrically connected to the SJ-MOSFET are adversely affected. On the other hand, when the area of the pn junctions between the p-type column regions 204 and the n-type column regions 203 is reduced, changes in the reverse recovery current of the body diodes become gradual, however, an effect of reducing the on-resistance by the parallel pn layer 202 disappears. Further, in switching applications of inverter circuits connected to an inductive load, the reverse recovery current of the body diodes of the SJ-MOSFET is consumed by the inductive load of the inverter circuit and thus, when the peak value of the reverse recovery current of the body diodes of the SJ-MOSFET is large, switching loss increases. Thus, in the present embodiment, for example, reverse recovery characteristics of the body diodes is improved.

Further, in general, SJ-MOSFETs are not intended for bidirectional conduction (forward bias and reverse bias of the body diode). For example, in an instance in which a SJ-MOSFET is used in a switching application of an inverter circuit connected to an inductive load, breakdown voltage cannot be maintained with respect to reverse conduction (forward conduction of body diodes of the SJ-MOSFET) of freewheeling current that flows during deadtime in inverter operation. As a result, diodes are required as individual components to prevent reverse conduction of the freewheeling current, and the increase in the number of individual components increases the cost of the product (semiconductor circuit device). Thus, for example, in the present embodiment, costs are reduced by reducing the number of individual components in a product equipped with a SJ-MOSFET.

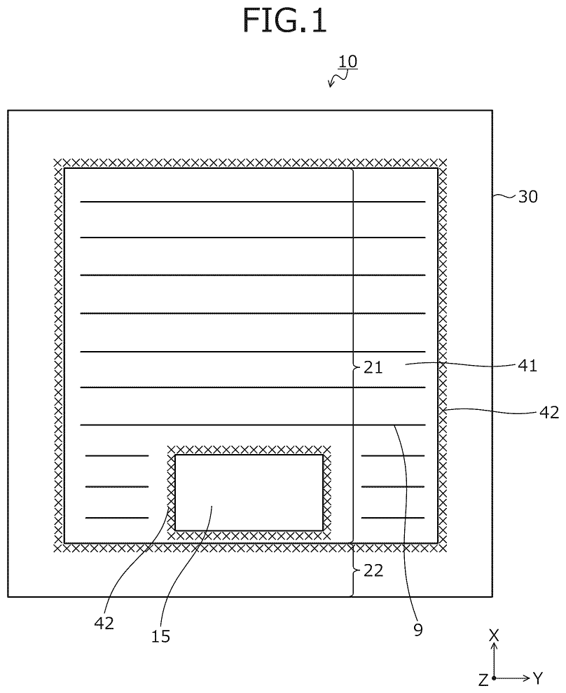

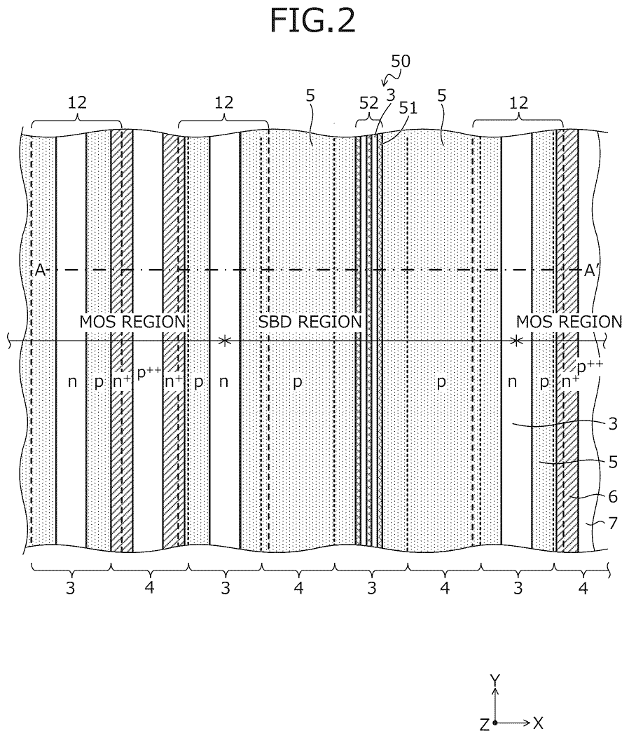

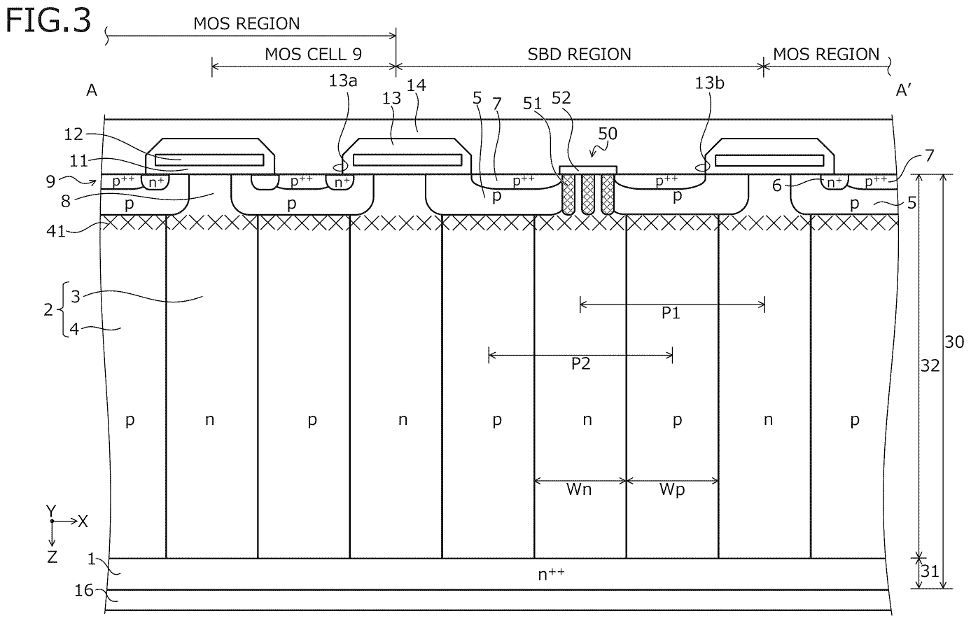

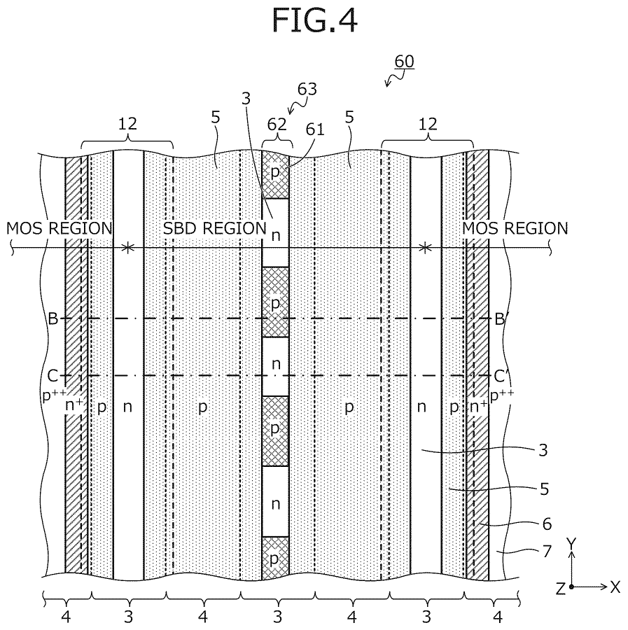

A structure of a semiconductor device according to a first embodiment is described. FIG. 1 is a plan view depicting a layout when the semiconductor device according to the first embodiment is viewed from a front surface of a semiconductor substrate thereof. In FIG. 1, MOS cells 9 and SBD cells of an SBD 50 are depicted as solid lines indicated by reference number 9 and extend in a stripe-like pattern in a horizontal direction. FIG. 2 is a plan view depicting an enlarged view of a portion of an active region in FIG. 1. FIG. 2 depicts a layout of p-type regions 51 of one SBD cell of the SBD 50. In FIG. 2, interfaces between n-type column regions 3 and p-type column regions 4 are indicated by dotted lines and ends of gate electrodes 12 are indicated by dashed lines (similarly in FIG. 4). FIG. 3 is a cross-sectional view of the structure along cutting line A-A′ in FIG. 2.

A semiconductor device 10 according to the first embodiment depicted in FIGS. 1 to 3 is a SJ-MOSFET with a super junction (SJ) structure in which a drift layer is constituted by a parallel pn layer 2; the semiconductor device 10 has a semiconductor substrate (semiconductor chip) 30 that contains SiC as a semiconductor material and in an active region 21 of the semiconductor substrate 30, the SBD 50 is provided in a flat plate-like shape parallel to a front surface of the semiconductor substrate 30. The active region 21 has a substantially rectangular shape in a plan view and is disposed in substantially a center of the semiconductor substrate 30. In a center portion of the active region 21, multiple cells (hereinafter, MOS cells) 9 each having a same MOSFET structure (herein, a planar gate structure) partially sandwich a cell (hereinafter, SBD cell) of the SBD 50 and are disposed adjacently in the first direction X, which is parallel to the front surface of the semiconductor substrate 30. The MOS cells 9 and the SBD cell extend in a stripe-like pattern in the second direction Y, which is parallel to the front surface of the semiconductor substrate 30 and orthogonal to the first direction X.

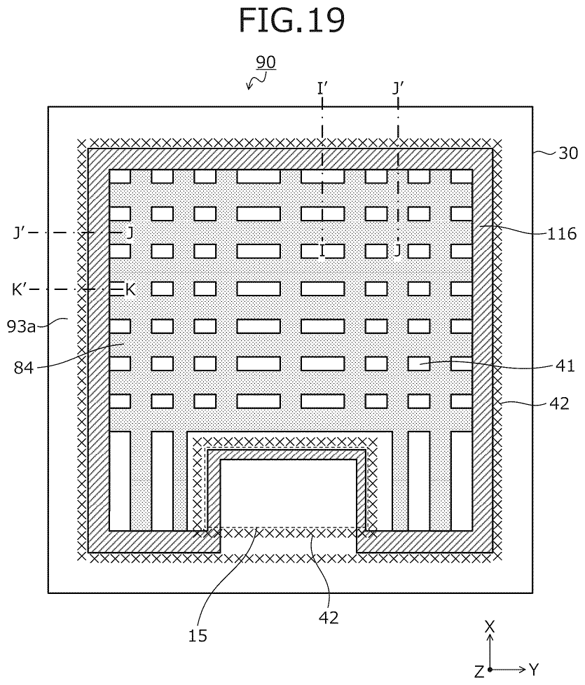

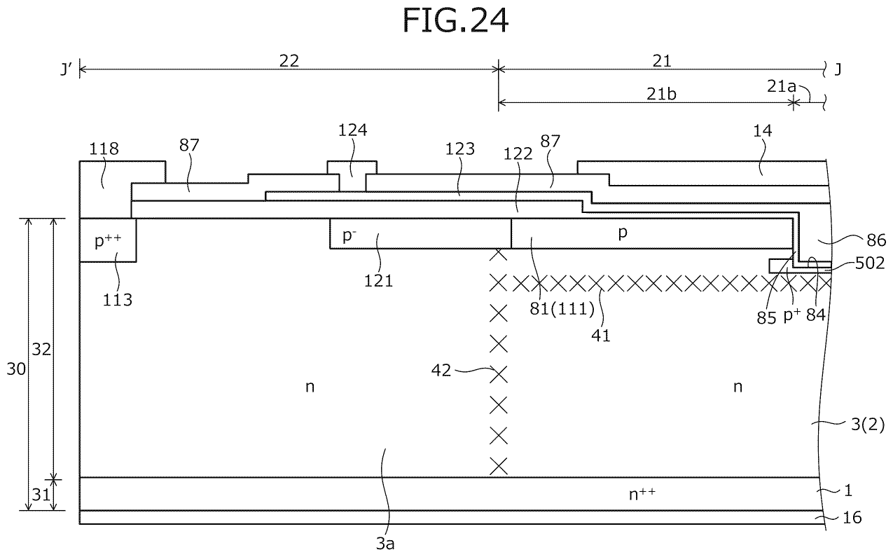

On the front surface of the semiconductor substrate 30, a source pad (a source electrode 14, not depicted in FIG. 1) is provided in the center portion of the active region 21 while a gate pad 15 and a gate finger (not depicted) are provided in an outer peripheral portion 21b (refer to FIGS. 19 to 24) of the active region 21; the outer peripheral portion 21b surrounds a periphery of the center portion of the active region 21 in a plan view. In a plan view, the source pad has a shape that is substantially a same as a shape of the center portion of the active region 21 and covers substantially an entire area of the center portion of the active region 21. The source pad, for example, may have a substantially rectangular shape that is partially recessed toward a chip center (center of the semiconductor substrate 30) so as to surround three sides of the substantially rectangular shaped gate pad 15 in a plan view. The gate pad 15 is electrically connected to the gate electrodes 12 (refer to FIG. 3) of all the MOS cells 9 via the gate finger.

Across an entire area of the active region 21, at a depth position (refer to FIG. 3) directly beneath p-type base regions 5 (sides of the p-type base regions 5 facing an n⁺⁺-type drain region 1), a low carrier lifetime region (first low carrier lifetime region) 41 is provided. Preferably, closer to an end of the semiconductor substrate 30 than are ends of the p-type base regions 5, a low carrier lifetime region (second low carrier lifetime region) 42 (indicated by “x”) may be provided so as to surround a periphery of the active region 21 in a plan view. Further, preferably, the low carrier lifetime region 42 may be further provided so as surround a periphery of the gate pad 15. Preferably, the low carrier lifetime region 42 may reach the n⁺⁺-type drain region 1 in a depth direction Z from the front surface of the semiconductor substrate 30 and may terminate in the n⁺⁺-type drain region 1 or may terminate at a back surface of the semiconductor substrate 30.

The low carrier lifetime regions 41, 42 are regions in which a lifetime of minority carriers (holes) is made relatively short by introducing therein a carrier lifetime killer (crystal defect that acts as a trapping center for minority carriers: first and second carrier lifetime killers) and at least the low carrier lifetime region 41 is provided. The carrier lifetime of the semiconductor substrate 30 is shortest in the low carrier lifetime regions 41, 42. The low carrier lifetime regions 41, 42 have a function of limiting a current path (path of hole current) during reverse recovery (recovery) of parasitic pn junction diodes (body diodes) to the active region 21, the parasitic pn junction diodes being formed by pn junctions (refer to FIG. 3) between the p-type base regions 5, the p-type column regions 4, and the n-type column regions 3 of the SJ-MOSFET.

An edge termination region 22 is a region between the active region 21 and the chip end (the end of the semiconductor substrate 30) and surrounds the periphery of the active region 21 in a substantially rectangular shape, in a plan view. The edge termination region 22 is a region closer to the chip end than are the ends of the p-type base regions 5. The edge termination region 22 has a function of relaxing electric field of a front side of the semiconductor substrate 30 and sustaining a breakdown voltage. The breakdown voltage is a voltage limit at which voltage between a drain and source does not further increase even when current between the drain and source increases due to avalanche breakdown by pn junctions. In the edge termination region 22, a predetermined voltage withstanding structure such as a junction termination extension (JTE) structure and a field limiting ring (FLR) structure is disposed. The structure of the edge termination region 22 is described in detail hereinafter.

As depicted in FIG. 3, the semiconductor substrate 30 is formed by growing an epitaxial layer 32 having the parallel pn layer 2 therein, on a front surface of an n⁺⁺-type starting substrate 31 that contains SiC. The semiconductor substrate 30 has, as the front surface, a main surface that is a surface of the epitaxial layer 32 and, as the back surface, a main surface that is a surface of the n⁺⁺-type starting substrate 31. The n⁺⁺-type starting substrate 31 constitutes the n⁺⁺-type drain region (first-conductivity-type high-concentration region) 1. The parallel pn layer 2 is formed by adjacently disposing the n-type column regions (first-conductivity-type column regions) 3 and the p-type column regions (second-conductivity-type column regions) 4 to repeatedly alternate with each other in the first direction X. The n-type column regions 3 and the p-type column regions 4 are in contact with the n⁺⁺-type drain region 1. Each of the n-type column regions 3 and each of the p-type column regions 4 extend linearly in the second direction Y and form a rectangular column shape that extends linearly in the depth direction Z.

The n-type column regions 3 and the p-type column regions 4 both form striped patterns in both a plan view and a cross-sectional view. In other words, the n-type column regions 3 and the p-type column regions 4 are disposed at predetermined repeat pitches P1, P2 in a lateral direction (the first direction X) and may extend linearly having substantially the same widths Wn, Wp in a longitudinal direction (the second direction Y) and may extend linearly having substantially the same widths Wn, Wp in the depth direction Z. The n-type column regions 3 and the p-type column regions 4 may terminate in the edge termination region 22 in the longitudinal direction.

Provided that charge between the n-type column regions 3 and the p-type column regions 4 that are adjacent to each other is roughly balanced, the width Wn and dopant concentration of the n-type column regions 3 may be different from the width Wp and the dopant concentration of the p-type column regions 4. Charge being balanced means that a first amount of dopant represented by a product of the width Wn and the carrier concentration (number of activated dopants per unit volume) of the n-type column regions 3 and a second amount of dopant represented by a product of the width Wp and the carrier concentration of the p-type column regions 4 are substantially the same (being substantially the same means that the second amount of dopant is within a range of 95% to 105% with respect to the first amount of dopant) and the amount of charge is balanced between the n-type column regions 3 and the p-type column regions 4 that are adjacent to each other. Substantially the same dopant concentration (carrier concentration) and substantially the same width means, respectively, the same dopant concentration and the same width within respective ranges that include allowable error due to manufacturing process variation.

In the active region 21, p-type base regions (first semiconductor regions) 5, n⁺-type source regions (plurality of second semiconductor regions) 6, p⁺⁺-type contact regions 7, and JFET regions 8 are each selectively provided between the front surface of the semiconductor substrate 30 and the parallel pn layer 2. The p-type base regions 5, the n⁺-type source regions 6, and the p⁺⁺-type contact regions 7 are diffused regions formed in surface regions (portions of the semiconductor substrate 30, at the front surface thereof) of the epitaxial layer 32 by ion implantation and thermal diffusion. The p-type base regions 5 are provided between the front surface of the semiconductor substrate 30 and the p-type column regions 4 and have lower surfaces (surfaces facing the n⁺⁺-type drain region 1) that are in contact with the p-type column regions 4. In the first direction X, a width of each of the p-type base regions 5 is wider than a width of each of the p-type column regions 4 and each of the p-type base regions 5, at both ends (side surfaces) thereof in the first direction X, is in contact with the n-type column regions 3 adjacent thereto.

The n⁺-type source regions 6 and the p⁺⁺-type contact regions 7 are selectively provided between the front surface of the semiconductor substrate 30 and the p-type base regions 5, are partially bordered by the p-type base regions 5, and are exposed by later-described contact holes 13a. The n⁺-type source regions 6 are provided at positions closer to the gate electrodes 12 than are the p⁺⁺-type contact regions 7. The p⁺⁺-type contact regions 7 may be omitted. In this instance, instead of the p⁺⁺-type contact regions 7, the p-type base regions 5 reach the front surface of the semiconductor substrate 30 and are exposed by the contact holes 13a. The JFET regions 8 are configured by portions of the n-type column regions 3, which extend so as to reach the front surface of the semiconductor substrate 30, said portions of the n-type column regions 3 being adjacent to the p-type base regions 5 in the first direction X.

The gate electrodes 12 are provided on the front surface of the semiconductor substrate 30 via gate insulating films 11. The gate electrodes 12 cover regions of the p-type base regions 5, via the gate insulating films 11, said regions of the p-type base regions 5 being between the n⁺-type source regions 6 and the JFET regions 8. The gate electrodes 12 cover the entire surface of each of the JFET regions 8 via the gate insulating films 11 and in the depth direction Z, face the n-type column regions 3 via the JFET regions 8. One of the p-type base regions 5, two of the n⁺-type source regions 6, one of the p⁺⁺-type contact regions 7, portions of two of the JFET regions 8, portions of two of the gate insulating films 11, and portions of adjacent two of the gate electrodes 12 that are disposed between centers of the adjacent two of the gate electrodes 12 configure one of the MOS cells 9 of the planar gate structure of the MOSFET.

The MOS cells 9 are disposed regularly, partially sandwiching the SBD cells (cells of the SBD 50). In particular, in the first direction X, for every one or more of the MOS cells 9 disposed (disposed adjacently in an instance of two or more), one SBD cell of the SBD 50 is disposed adjacently to the MOS cells 9. All the cells (the MOS cells 9 and the SBD cells) are disposed in a stripe-like shape extending in the second direction Y. In FIG. 2, a region in which one or more of the MOS cells 9 is disposed (adjacently in an instance of two or more) is indicated as “MOS region” and a region in which one SBD cell is disposed is indicated as a “SBD region” (similarly in FIGS. 4, 7, and 13). In FIG. 3, the MOS cells 9, which are disposed adjacently, and an SBD cell adjacent to said MOS cells 9 is disposed. One SBD cell and SBD region form a same shape in a plan view. It is sufficient to obtain a predetermined current capability of the SJ-MOSFET by a predetermined chip size, and the repeat pitch of the SBD cell is set appropriately.

Some of the n-type column regions 3 reach the front surface of the semiconductor substrate 30 (hereinafter, the n-type column regions 3 configuring the SBD 50) and the SBD 50 is a Schottky barrier diode employing rectification of Schottky barriers formed at junction surfaces between the n-type column regions 3 configuring the SBD 50 and conductive films 52 that are in contact with the n-type column regions 3 configuring the SBD 50, at the front surface of the semiconductor substrate 30. The SBD 50 is connected in parallel to body diodes of the SJ-MOSFET. The SBD 50 extends linearly along the n-type column regions 3 configuring the SBD 50 in the second direction Y. One SBD cell of the SBD 50 is configured in a portion between the centers of the gate electrodes 12 adjacent to each other across Schottky junctions between one of the conductive films 52 and portions of one of the n-type column regions 3 configuring the SBD 50. The SBD cell (i.e., the SBD region) is free of the n⁺-type source regions 6. In the SBD cell, the p⁺⁺-type contact regions 7 may be provided.

In other words, between the front surface of the semiconductor substrate 30 and the parallel pn layer 2, instead of the p-type base regions 5, the n⁺-type source regions 6, the JFET regions 8, the gate insulating films 11, and the gate electrodes 12, Schottky junctions between one of the conductive films 52 and portions of one of the n-type column regions 3 configuring the SBD 50 are formed, whereby one SBD cell (i.e., one SBD region) of the SBD 50 is configured. The SBD 50 is disposed between the p-type base regions 5. The SBD 50 may have a junction barrier Schottky (JBS) structure in which both Schottky junctions between the conductive films 52 and the portions of the n-type column regions 3 configuring the SBD 50, and pn junctions between the p-type regions (portion with lattice-pattern hatching: third semiconductor regions) 51 and the portions of the n-type column regions 3 configuring the SBD 50 are present.

The p-type regions 51 are selectively provided in plural (herein, three) between the front surface of the semiconductor substrate 30 and the n-type column regions 3 configuring the SBD 50. The p-type regions 51 extend in a stripe-like shape in the second direction Y, between the p-type base regions 5 that are adjacent to each other. Of the p-type regions 51, ones closest to the p-type base regions 5 may be in contact with the p-type base regions 5 (or further in contact with the p⁺⁺-type contact regions 7). Portions of the n-type column regions 3 that are directly beneath the p-type regions 51 adjacent to each other extend between the adjacent p-type regions 51 and are exposed together with the p-type regions 51 by later described contact holes 13b. The dopant concentration, arrangement interval, width, and number of the p-type regions 51 configuring the JBS structure of the SBD cells are suitably set according to the dopant concentration of the n-type column regions 3.

The p-type regions 51 are diffused regions formed in surface regions of the epitaxial layer 32 by ion implantation and thermal diffusion. The p-type regions 51, for example, may be formed concurrently with the p-type base regions 5 and may have substantially the same dopant concentration and substantially the same depth as the dopant concentration and the depth of the p-type base regions 5. Ion implantation for forming the p-type base regions 5 and ion implantation for forming the p-type regions 51 may be performed separately in the order stated (or in reverse of the order stated). It suffices for depletion of surface regions of the n-type column regions 3 to be promoted by the p-type regions 51 during reverse recovery of the body diodes of the SJ-MOSFET and the dopant concentration of the p-type regions 51 may be higher than the dopant concentration of the p-type base regions 5 and the depth of the p-type regions 51 may be shallower than the depth of the p-type base regions 5.

The p-type regions 51 are depleted during reverse recovery of the body diodes of the SJ-MOSFET (or cause the surface regions of the n-type column regions 3 configuring the SBD 50 to deplete, or both) and have a function of relaxing electric field applied to the SBD 50. Further, during reverse recovery of the body diodes of the SJ-MOSFET, depletion of the surface regions of the n-type column regions 3 configuring the SBD 50 is promoted by the p-type regions 51. As a result, minority carriers (holes) in the n-type column regions 3 configuring the SBD 50 decrease and recombination of carriers near the pn junctions between the p-type column regions 4 and the n-type column regions 3 configuring the SBD 50 is suppressed, whereby changes in the reverse recovery current of the body diodes of the SJ-MOSFET are gradual (soft recovery).

The conductive films 52 are provided on the front surface of the semiconductor substrate 30 in the contact holes 13b; the conductive films 52 extend linearly in the second direction Y and cover the p-type regions 51 and the n-type column regions 3 configuring the SBD cell. In an instance in which the MOS cells 9 are an n-channel type, molybdenum (Mo) may be used as a metal material of the conductive films 52. The conductive films 52 may have a function of a barrier metal that prevents interaction and diffusion of atoms between the source electrode 14 and the semiconductor substrate 30. In an instance in which the conductive films 52 function as a barrier metal, the conductive films 52 may be provided in an entire area between the source electrode 14 and the semiconductor substrate 30 and an interlayer insulating film 13, in the active region 21. For example, titanium (Ti) may be used as a metal material to function as a barrier metal.

The low carrier lifetime region 41 is provided across an entire area of the active region 21, at a depth position directly beneath the p-type base regions 5 and in the depth direction Z, is adjacent to the p-type base regions 5, the JFET regions 8, and the SBD 50. The low carrier lifetime region 41 has a function of promoting recombination of carriers (electrons and holes) during reverse recovery of the body diodes of the SJ-MOSFET and decreasing the amount of effective (apparent) reverse recovery current of the body diodes. The low carrier lifetime region 41 is formed by irradiating the semiconductor substrate 30 with light ions such as protons (H+) and helium (He), which can partially introduce lifetime killers into the substrate.

The low carrier lifetime region 41 is present in the n-type column regions 3 configuring the SBD 50 directly beneath the SBD 50, whereby the n-type column regions 3 configuring the SBD 50 have a lower resistance and while forward current easily flows in the SBD 50, the amount of irradiation of the light ions for forming the low carrier lifetime region 41 is suitably adjusted and thus, it is expected that this will not adversely affect the operation of SJ-MOSFETs. The irradiation of the light ions to form the low carrier lifetime region 41, for example, suffices to be performed from the front surface or the back surface of the semiconductor substrate 30 with an irradiation dose in a range of about 1×10¹¹/cm² to 1×10¹³/cm² and an acceleration voltage in a range of about 100 keV to 2 MeV.

The interlayer insulating film 13 is provided in an entire area of the front surface of the semiconductor substrate 30 and covers the gate electrodes 12. In the interlayer insulating film 13, the contact holes 13a are provided for each of the MOS cells 9, and the contact holes 13b are provided for each SBD cell of the SBD 50. The contact holes 13a, 13b extend in stripe-like shapes in the second direction Y. The source electrode (first electrode) 14 is provided on the interlayer insulating film 13 so as to be embedded in the contact holes 13a, 13b. The source electrode 14 is in ohmic contact with the n⁺-type source regions 6 and the p⁺⁺-type contact regions 7 in the contact holes 13a. The source electrode 14 is in contact with the conductive films 52 in the contact holes 13b. The source electrode 14 may be in contact with the p-type base regions 5 and the p⁺⁺-type contact regions 7 in the contact holes 13b. A drain electrode (second electrode) 16 is provided in an entire area of the back surface of the semiconductor substrate 30 (back surface of the n⁺⁺-type starting substrate 31).

While not particularly limited hereto, for example, in an instance in which the semiconductor device 10 according to the first embodiment (SJ-MOSFET) is a 3.3 kV breakdown voltage class, dimensions and dopant concentrations of regions may have the following values. The repeat pitches P1, P2 of the n-type column regions 3 and the p-type column regions 4 are in a range of about 1.0 μm to 5.0 μm and may be, for example, about 3.0 μm. Dopant concentrations of the n-type column regions 3, the p-type column regions 4, the p-type base regions 5, and the p-type regions 51 are about 1.0×10¹⁶/cm³. A dopant concentration of the n⁺-type source regions 6 is about 1.0×10¹⁷/cm³. Dopant concentrations of the n⁺⁺-type drain region 1 and the p⁺⁺-type contact regions 7 are in a range of about 1.0×10¹⁸/cm³ to 1.0×10¹⁹/cm³.

Next, operation of the semiconductor device 10 according to the first embodiment (SJ-MOSFET) is described. When voltage that is positive with respect to the source electrode 14 is applied to the drain electrode 16 and voltage that is at least equal to the gate threshold voltage is applied to the gate electrodes 12, a channel (n-type inversion layer) is formed in the regions of the p-type base regions 5, between the n⁺-type source regions 6 and the JFET regions 8. As a result, drift current (main current) flows from the n⁺⁺-type drain region 1, through the n-type column regions 3 and the channel, to the n⁺-type source regions 6 and the SJ-MOSFET turns on.

On the other hand, when voltage that is positive with respect to the source electrode 14 is applied to the drain electrode 16 and the voltage that is applied to the gate electrodes 12 is lower than the gate threshold voltage, the pn junctions between the p-type base regions 5, the p-type column regions 4, and the n-type column regions 3 are reverse biased and thus, the SJ-MOSFET maintains the off-state. A depletion layer spreads vertically (toward the source electrode 14 and toward the drain electrode 16) from the pn junctions between the p-type base regions 5 and the n-type column regions 3 and a depletion layer spreads horizontally from the pn junctions between the p-type column regions 4 and the n-type column regions 3.

The depletion layer spreading horizontally has a width that is half of the width Wn of each of the n-type column regions 3, whereby the drift layer of the thickness of the parallel pn layer 2 is depleted and a predetermined breakdown voltage of the active region 21 is maintained. The spreading of the depletion layer may be small as compared to a normal MOSFET in which the drift layer is configured by only an n-type region and thus, it is possible to increase the dopant concentration of the drift layer and lower the on-resistance. Further, corresponding to the extent which a depletion layer expands outward (toward the chip end) in the horizontal direction in the edge termination region 22, a predetermined breakdown voltage of the edge termination region 22 is maintained based on the breakdown field strength of the semiconductor material.

Further, during forward bias of the body diodes of SJ-MOSFET, the SBD 50 conducts in the forward direction sooner than the body diodes by a voltage lower than the threshold voltage of the body diodes of SJ-MOSFET. Thus, parasitic npn bipolar transistors (body diodes) formed by the n-type column regions 3, the p-type base regions 5, and the n⁺-type source regions 6 do not operate. As a result, for example, breakdown voltage may be maintained against reverse conduction (forward conduction of the body diode) of freewheeling current that flows during the dead time period in inverter operation.

Further, the body diodes of the SJ-MOSFET conduct during a period when the SJ-MOSFET transitions from on to off and electrons and holes are injected into and stored in the p-type column regions 4 and the n-type column regions 3, respectively. When the SJ-MOSFET has turned off (reverse recovery state of the body diodes) from this state, carriers (electrons and holes) in the parallel pn layer 2 are discharged to the drain electrode 16 and the source electrode 14, and current (the reverse recovery current of the body diodes) flows in the reverse direction in the pn junctions between the p-type base regions 5 and the n-type column regions 3.

While the carriers in the parallel pn layer 2 decrease as a result of the reverse recovery current flowing, the carriers in the parallel pn layer 2 are discharged to the drain electrode 16 and the source electrode 14, whereby a depletion layer spreads vertically from the pn junctions between the p-type base regions 5 and the n-type column regions 3 and the reverse voltage applied to the pn junctions increases. The reverse voltage applied to the pn junctions between the p-type column regions 4 and the n-type column regions 3 also increases, recombination of the carriers near the pn junctions between the p-type column regions 4 and the n-type column regions 3 progresses, and the carriers disappear from the parallel pn layer 2 in a short period of time.

During reverse recovery of the body diodes of the SJ-MOSFET, the SBD 50, which is partially disposed in the active region 21 and connected in parallel to the MOS cells 9, is also reverse biased and the surface region of the n-type column regions 3 configuring the SBD 50 is depleted. As a result, the number of minority carriers in the n-type column regions 3 configuring the SBD 50 decreases and thus, is essentially the same as reducing the area of the junctions between the p-type column regions 4 and the n-type column regions 3 configuring the SBD 50. Thus, changes in the reverse recovery current of the body diodes of the SJ-MOSFET may be made to be gradual.

The area of the junctions between the p-type column regions 4 and the n-type column regions 3 configuring the SBD 50 needs not be reduced and thus, the effect of reducing the on-resistance by the parallel pn layer 2 is maintained while the reverse recovery characteristics of the body diodes of SJ-MOSFET may be made to exhibit soft recovery. Further, the number of minority carriers in the n-type column regions 3 configuring the SBD 50 decreases and thus, the peak value of the reverse recovery current of the body diodes of the SJ-MOSFET decreases, whereby in switching applications of inverter circuits connected to an inductive load, switching loss may be reduced.

As described above, according to the first embodiment, in the SJ-MOSFET, the drift layer is a parallel pn layer constituted by the n-type column regions and the p-type column regions, the parallel pn layer increases the breakdown voltage, and the on-resistance may be lowered by increasing the dopant concentration of the drift layer. Further, according to the first embodiment, in the active region, the SBD is formed by the Schottky junctions between the conductive films and the n-type column regions configuring the SBD. When the body diodes of SJ-MOSFET are forward biased, the SBD conducts in the forward direction sooner than the body diodes of SJ-MOSFET, whereby, for example, breakdown voltage may be maintained with respect to reverse conduction of freewheeling current that flows during deadtime in inverter operation. Further, the SBD is built into a single semiconductor substrate in which the SJ-MOSFET is provided, whereby the number of individual components in a product equipped with the SJ-MOSFET is reduced and costs may be reduced.

Further, according to the first embodiment, in the active region, the SBD formed by the Schottky junctions between the conductive films and the n-type column regions configuring the SBD maintains the effect of reducing the on-resistance by the parallel pn layer while changes in the reverse recovery current of the body diodes of the SJ-MOSFET may be made to be gradual. Further, across an entire area of the active region, at a depth position directly beneath the p-type base regions, the low carrier lifetime region is provided, whereby the amount of effective (apparent) reverse recovery current of the body diodes of the SJ-MOSFET may be decreased. As a result, changes in the reverse recovery current of the body diodes of the SJ-MOSFET may be made to be gradual. Further, the peak value of the reverse recovery current of the body diodes of the SJ-MOSFET decreases and in switching applications of inverter circuits connected to an inductive load, switching loss may be reduced. Thus, reverse recovery characteristics of the body diodes may be improved.

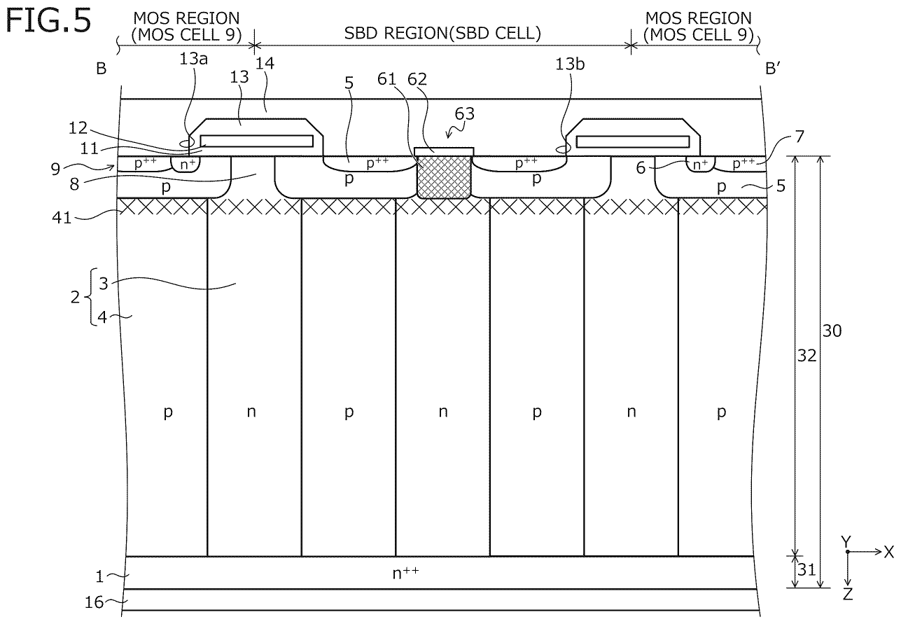

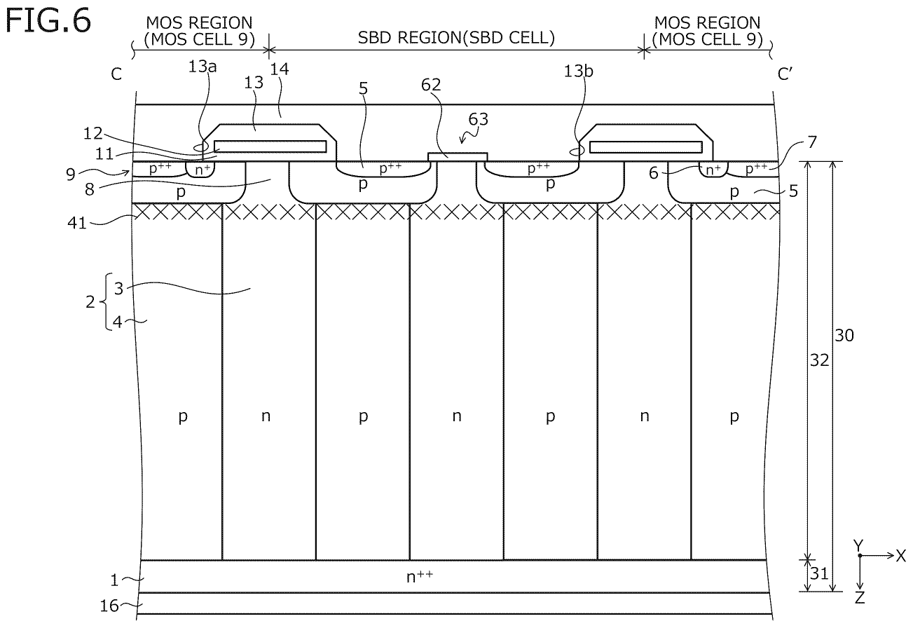

A structure of a semiconductor device according to a second embodiment is described. FIG. 4 is a plan view depicting a layout when a portion of the active region of the semiconductor device according to the second embodiment is viewed from the front surface of the semiconductor substrate. An overall layout of a semiconductor device 60 according to the second embodiment when viewed from the front surface of the semiconductor substrate 30 is a same as the layout in FIG. 1. FIG. 4 is an enlarged view of a portion of the active region 21 in FIG. 1 and depicts a layout of p-type regions 61 (portions with lattice-pattern hatching) of one SBD cell of an SBD 63. FIGS. 5 and 6 are cross-sectional views of the structure along cutting line B-B′ and cutting line C-C′ in FIG. 4, respectively.

In the semiconductor device 60 according to the second embodiment depicted in FIGS. 4 to 6, the layout of the p-type regions 61 configuring a JBS structure of SBD cells of the SBD 63 is different from the layout of the semiconductor device 10 according to the first embodiment (refer to FIGS. 2 and 3). An SBD cell of the SBD 63 is a diode with a JBS structure in which both Schottky junctions between conductive films 62 and the n-type column regions 3, and pn junctions between the p-type regions 61 and the n-type column regions 3 configuring the SBD 63 are present. The SBD cells of the SBD 63, similarly to the SBD cells of the SBD 50 of the first embodiment, are disposed between the p-type base regions 5 that are adjacent to each other and each of the SBD cells of the SBD 63 extends in a stripe-like shape in the second direction Y together with the MOS cells 9.

The p-type regions 61 are provided interspersed in the second direction Y, between the p-type base regions 5 that are adjacent to each other. Each of the p-type regions 61 has a width that is substantially a same as an interval between the p-type base regions 5 that are adjacent to each other and both sides of each of the p-type regions 61 in the first direction X are in contact with the p-type base regions 5 (or also in contact with the p⁺⁺-type contact regions 7). The n-type column regions 3 configuring the SBD 63 and directly beneath the p-type regions 61 adjacent to each other in the second direction Y extend between the adjacent p-type regions 61 and are exposed in the contact holes 13b together with the p-type regions 61. In other words, in the second direction Y, the p-type regions 61 and portions of the n-type column regions 3 configuring the SBD 63 are adjacent to each other and repeatedly alternate with each other between the p-type base regions 5 that are adjacent to each other.

A width in the second direction Y, a repeat pitch in the second direction Y, and a dopant concentration of each of the p-type regions 61 are suitably set according to the dopant concentration of the n-type column regions 3. The width in the second direction Y and the repeat pitch of the p-type regions 61 may be, for example, in a range of about 1.0 μm to 5.0 μm and, for example, about 3.0 μm, respectively. Configuration of the conductive films 62 is the same as the configuration of the conductive films 52 of the SBD 50 of the first embodiment. In other words, the conductive films 62 are provided on the front surface of the semiconductor substrate 30, in the contact holes 13b of the interlayer insulating film 13 and extend linearly in the second direction Y; the conductive films 62 cover the n-type column regions 3 and the p-type regions 61 configuring the SBD cells.

As described above, according to the second embodiment, even when the layout of the p-type regions configuring the JBS structure of the SBD disposed adjacent to the MOS cells is variously changed, effects similar to those of the first embodiment may be obtained.

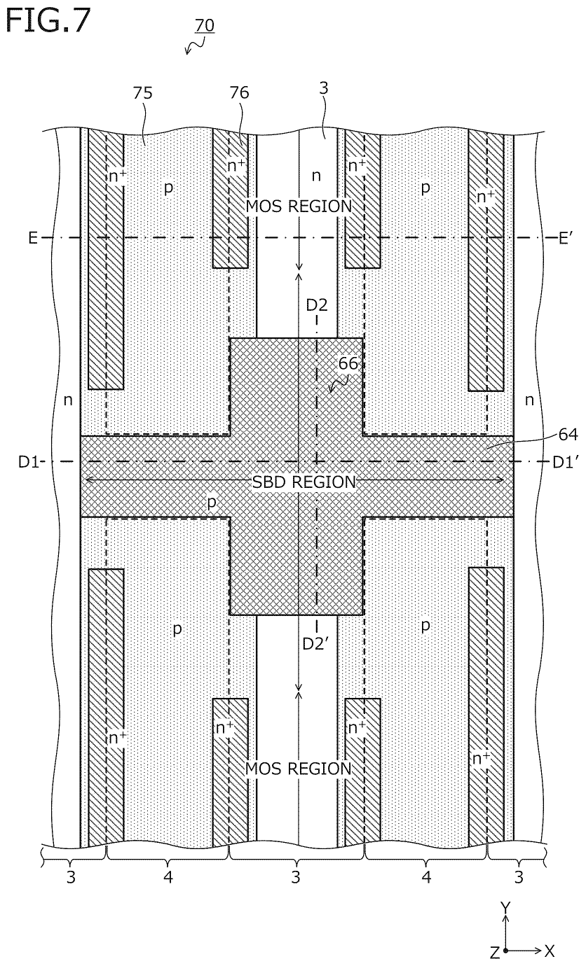

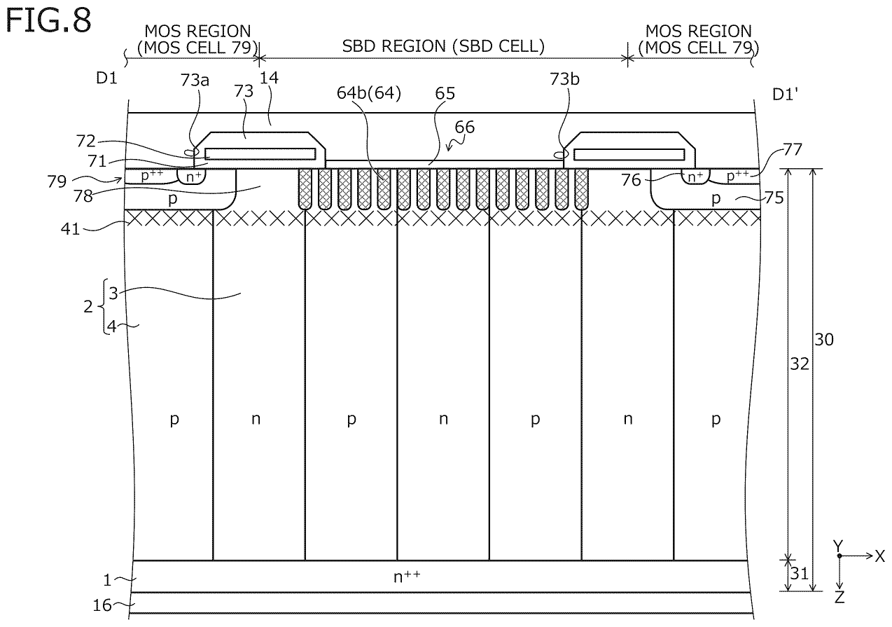

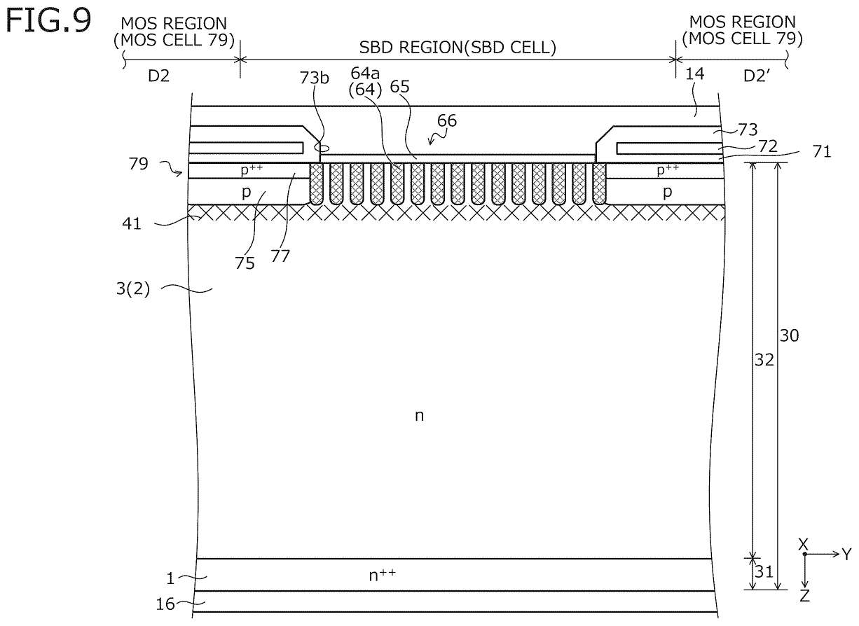

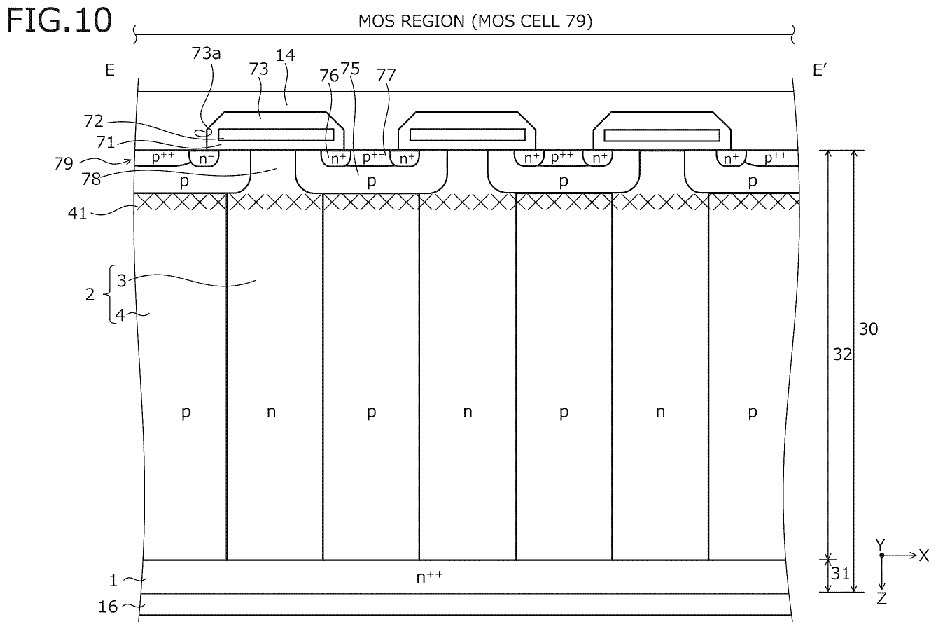

A structure of a semiconductor device according to a third embodiment is described. FIG. 7 is a plan view depicting a layout when a portion of the active region of the semiconductor device according to the third embodiment is viewed from the front surface of the semiconductor substrate. An overall layout of a semiconductor device 70 according to the third embodiment, when viewed from the front surface of the semiconductor substrate 30, is the same as the layout in FIG. 1 except for the layout of MOS cells 79 and SBD cells of a SBD 66. In FIG. 7, multiple p-type regions 64 configuring a JBS structure of the SBD cells of the SBD 66 are collectively depicted as a single region (portion with lattice-pattern hatching). FIGS. 8, 9, and 10 are cross-sectional views of the structure along cutting line D1-D1′, cutting line D2-D2′, and cutting line E-E′ in FIG. 7, respectively.

The semiconductor device 70 according to the third embodiment depicted in FIGS. 7 to 10 differs from the semiconductor device according to the first embodiment (refer to FIG. 2) in that the MOS cells 79 and the SBD cells of the SBD 66 are disposed in a matrix-like pattern. In particular, the MOS cells 79 and the SBD cells of the SBD 66 each have a substantially rectangular shape of a same size in a plan view. The MOS cells 79 are disposed in a matrix-like pattern and partially sandwich the SBD cells of the SBD 66. In other words, in both the first and second directions X, Y, for every one or more of the MOS cells 79 (disposed adjacently in an instance of two or more), one SBD cell of the SBD 66 is disposed adjacent to said MOS cells 79. Preferably, the SBD cells of the SBD 66 may be regularly interspersed. The MOS cells 79 and the SBD cells of the SBD 66 may be disposed in a checker-board-like pattern, adjacent to and repeatedly alternating with each other in both the first and second directions X, Y.

In a plan view, a layout of p-type base regions 75, n⁺-type source regions 76, p⁺⁺-type contact regions 77 (in FIG. 7, the p⁺⁺-type contact regions 77 are not depicted), and JFET regions 78 configuring a planar gate structure of the MOS cells 79 differs from the layout of the MOS cells 9 of the first embodiment (refer to FIG. 2). The p-type base regions 75, the n⁺-type source regions 76, the p⁺⁺-type contact regions 77, the JFET regions 78, gate insulating films 71, gate electrodes 72, and contact holes 73a of the MOS cells 79 extend linearly in the second direction Y and are partially interrupted (detached) by the SBD regions (regions in which one SBD cell of the SBD 66 is disposed). The n⁺-type source regions 76, the gate electrodes 72, and the contact holes 73a terminate at positions apart from the SBD regions in the second direction Y. The p-type base regions 75 (or also the p⁺⁺-type contact regions 77) terminate in an outer periphery of the SBD regions.

The SBD 66 is a diode employing rectification of Schottky barriers formed at junction surfaces between the n-type column regions 3 reaching the front surface of the semiconductor substrate 30 and conductive films 65 in contact with said n-type column regions 3, at the front surface of the semiconductor substrate 30. The SBD 66 may be a JBS structure in which the Schottky junctions of the conductive films 65 and said n-type column regions 3, and pn junctions between the p-type regions 64 and said n-type column regions 3 are both present. The p-type regions 64 configuring the JBS structure of the SBD cells are disposed in a grid-like pattern so as to form an overall cross-like shape in a plan view. In particular, the p-type regions 64 (hereinafter, first p-type regions 64a) that extend in stripe-like shapes in the first direction X between the p-type base regions 75 adjacent to each other in the first direction X and the p-type regions 64 (hereinafter, second p-type regions 64b) that extend in stripe-like shapes in the second direction Y between the p-type base regions 75 that are adjacent to each other in the second direction Y are disposed so as to form a cross-like shape in a plan view.

The first p-type regions 64a extend linearly in the first direction X between the front surface of the semiconductor substrate 30 and the parallel pn layer 2 so as to be in contact with the n-type column region 3 and the p-type column region 4 alternately. The n-type column regions 3 and the p-type column regions 4 directly below the first p-type regions 64a that are adjacent to each other extend between the adjacent first p-type regions 64a. The second p-type regions 64b extend linearly between the front surface of the semiconductor substrate 30 and the n-type column regions 3 or the p-type column regions 4, in the second direction Y along the n-type column regions 3 or the p-type column regions 4. The n-type column regions 3 or the p-type column regions 4, or junction surfaces between the n-type column regions 3 and the p-type column regions 4 extend between the second p-type regions 64b that are adjacent to each other. The p-type regions 64 are disposed apart from the n⁺-type source regions 76. The p-type regions 64 are in contact with the p-type base regions 75 (or also in contact with the p⁺⁺-type contact regions 77) in the first direction X.

An interlayer insulating film 73 is provided in an entire area of the front surface of the semiconductor substrate 30 and covers the gate electrodes 72. In the interlayer insulating film 73, the contact holes 73a are provided for each of the MOS cells 79 and contact holes 73b are provided for each of the SBD cells of the SBD 66. The contact holes 73a, 73b of the interlayer insulating film 73 have, in a plan view, substantially rectangular shapes; the contact holes 73a have an opening area that is smaller than the surface area of the MOS cells 79 and the contact holes 73b have an opening area that is smaller than the surface area of the SBD cells of the SBD 66. The contact holes 73a, 73b are disposed in a matrix-like pattern so that the interlayer insulating film 73 remains in a grid-like pattern. The conductive films 65 are provided in an entire area of the front surface of the semiconductor substrate 30, in the contact holes 73b. The conductive films 65 cover the p-type regions 64, and the n-type column regions 3 and the p-type column regions 4 between the p-type regions 64 that are adjacent to each other.

The JBS structure of the SBD 63 (refer to FIG. 4) of the semiconductor device 60 according to the second embodiment above may be applied to the SBD 66 of the semiconductor device 70 according to the third embodiment and the first and second p-type regions 64a, 64b of the SBD 66 may be interspersed in the first and second directions X, Y, respectively.

As described above, according to the third embodiment, even in an instance in which the cells are disposed in a matrix-like pattern, effects similar to the first embodiment may be obtained.

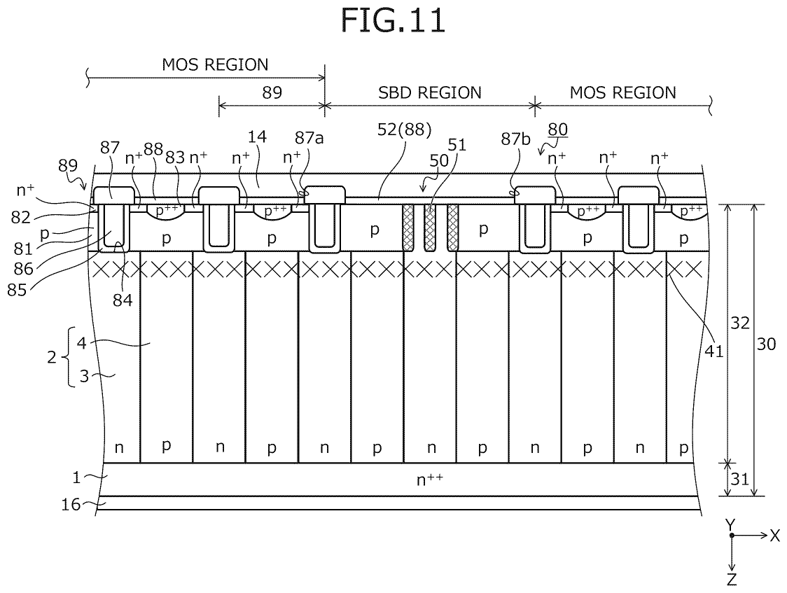

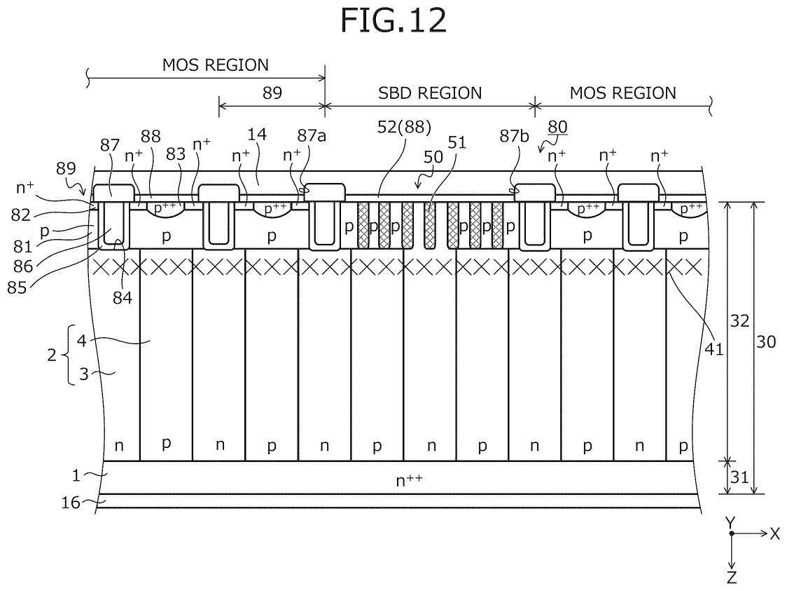

A structure of a semiconductor device according to a fourth embodiment is described. FIG. 11 is a cross-sectional view depicting the structure of the semiconductor device according to the fourth embodiment. FIG. 12 is a cross-sectional view depicting another example of the structure of the semiconductor device according to the fourth embodiment. An overall layout of a semiconductor device 80 according to the fourth embodiment, when viewed from the front surface of the semiconductor substrate 30 is the same as that in FIG. 1 where reference number 9 is replaced with reference number 89. The semiconductor device 80 according to the fourth embodiment depicted in FIGS. 11 and 12 is the semiconductor device according to the first embodiment (refer to FIG. 3) in which a trench gate structure is adopted. MOS cells 89 are the MOS cells 9 of the first embodiment in which the trench gate structure (insulated gate structure) is adopted.

In particular, in the fourth embodiment, the MOS cells 89, similar to the MOS cells 9 of the first embodiment, are disposed adjacent to each other in the first direction X, partially sandwiching SBD cells of the SBD 50 and extending in stripe-like shapes in the second direction Y. The MOS cells 89 constitute the trench gate structure formed by p-type base regions 81, n⁺-type source regions 82, p⁺⁺-type contact regions 83, trenches 84, gate insulating films 85, and gate electrodes 86. A portion between centers of the gate electrodes 86 adjacent to each other constitutes one of the MOS cells 89. The p-type base regions 81, the n⁺-type source regions 82, and the p⁺⁺-type contact regions 83 are each selectively provided between the front surface of the semiconductor substrate 30 and the parallel pn layer 2.

The p-type base regions 81, the n⁺-type source regions 82, and the p⁺⁺-type contact regions 83 are diffused regions formed in surface regions of the epitaxial layer 32 by ion implantation and thermal diffusion. The p-type base regions 81 are provided in the entire area of the MOS regions (regions in which one or more of the MOS cells 89 are disposed (disposed adjacently in an instance of two or more)). The n⁺-type source regions 82 and the p⁺⁺-type contact regions 83 are selectively provided between the front surface of the semiconductor substrate 30 and the p-type base regions 81. The trenches 84 penetrate through the n⁺-type source regions 82 and the p-type base regions 81 in the depth direction Z and reach the n-type column regions 3. In the trenches 84, the gate electrodes 86 are provided via the gate insulating films 85.

An interlayer insulating film 87 is provided in an entire area of the front surface of the semiconductor substrate 30 and covers the gate electrodes 86. In the interlayer insulating film 87, contact holes 87a are provided for each of the MOS cells 89 while contact holes 87b are provided for each SBD cell of the SBD 50. The contact holes 87a, 87b extend in stripe-like shapes in the second direction Y. In the contact holes 87a, 87b, a barrier metal 88 is provided in an entire area of the front surface of the semiconductor substrate 30. The barrier metal 88 contains a metal capable of forming an ohmic contact with the semiconductor substrate 30. The barrier metal 88 may have a stacked structure of two or more layers. The barrier metal 88 in the contact holes 87b constitutes the conductive films 52 of the SBD 50.

Schottky junctions between the conductive films 52 and the n-type column regions 3 configuring the SBD 50 are formed between the front surface of the semiconductor substrate 30 and the parallel pn layer 2, instead of the p-type base regions 81, the n⁺-type source regions 82, the trenches 84, the gate insulating films 85, and the gate electrodes 86, whereby one SBD cell (i.e., one SBD region) of the SBD 50 is configured. The SBD 50 is selectively disposed between the p-type base regions 81 that are adjacent to each other. Configuration of the SBD 50 is the same as the configuration in the first embodiment. The p-type regions 51 of the SBD 50 are in contact with the p-type base regions 81, similar to the first embodiment. The SBD cells (SBD regions) are free of the n⁺-type source regions 82. In the SBD cells, the p⁺⁺-type contact regions 83 may also be provided. The p-type regions 51 configuring the JBS structure of the SBD cells may be formed concurrently with the p-type base regions 81. Further, the p-type regions 51 may be formed at substantially the same depth as the p-type base regions 81 and may have substantially the same dopant concentration.

Of the p-type regions 51 configuring the JBS structure of the SBD cells, one or more of the p-type regions 51 may be disposed overlapping the p-type base regions 81 of the SBD cells (i.e., in the SBD region) (FIG. 12). In this instance, the p-type regions 51 overlapping the p-type base regions 81 are in contact with the p-type column regions 4. A dopant concentration of the p-type regions 51 is higher than a dopant concentration of the p-type base regions 81. The SBD 50 of the semiconductor device 80 according to the fourth embodiment depicted in FIG. 12 may be applied to the semiconductor devices 10, 60, 70 (refer to FIGS. 1 to 10) according to the first to third embodiments above and the p-type regions 51, 61, 64 of the SBD cells of the SBDs 50, 63, 66 of the first to third embodiments may be disposed overlapping the p-type base regions 5, 75 of the SBD cells.

Further, the semiconductor device 60 according to the second embodiment above (refer to FIGS. 4 to 6) may be applied to the semiconductor device 80 according to the fourth embodiment depicted in FIG. 11 and instead of the SBD 50, the SBD 63 may be disposed. Further, the semiconductor device 70 according to the third embodiment (refer to FIG. 7) may be applied to the semiconductor device 80 according to the fourth embodiment depicted in FIGS. 11 and 12 and the MOS cells 89 may be disposed in a matrix-like pattern, partially sandwiching the SBD cells of the SBD 66 of the third embodiment. In this instance, the p-type base regions 81, the n⁺-type source regions 82, the p⁺⁺-type contact regions 83, the trenches 84, the gate insulating films 85, the gate electrodes 86, and the contact holes 87a of the MOS cells 89 suffice to extend linearly in the second direction Y and be partially interrupted by the SBD regions.

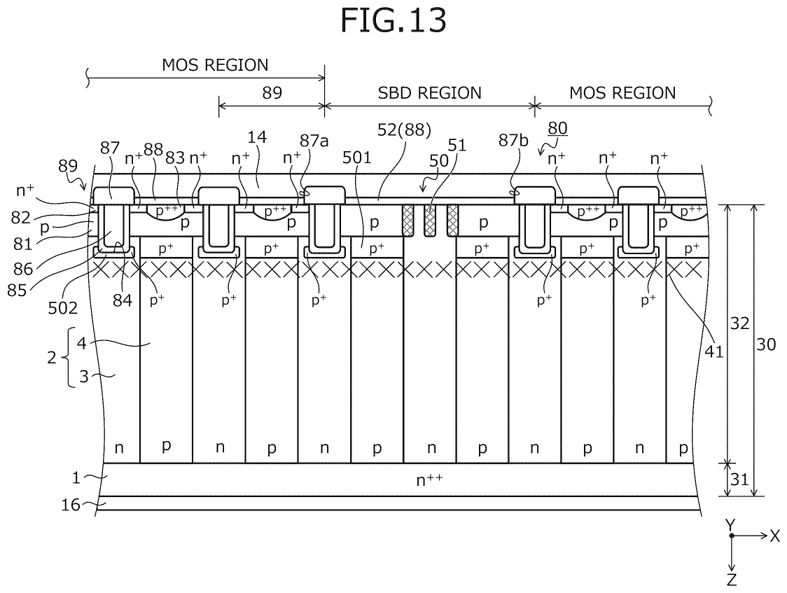

Another example of the semiconductor device 80 according to the fourth embodiment depicted in FIG. 13 has p⁺-type regions 501 selectively provided at sides of the p-type base regions 81, said sides facing the n⁺⁺-type drain region 1, and p⁺-type regions 502 disposed at lower portions of the trenches 84 so as to border bottoms of the trenches 84. The p⁺-type regions 501 connect the p-type base regions 81 and the p-type column regions 4. The p⁺-type regions 502 are provided at the lower portions of the trenches 84. The trenches 84 may terminate in the p⁺-type regions 502. The p⁺-type regions 502 have a function of relaxing electric field near the bottoms of the trenches 84. The p⁺-type regions 502 are provided apart from the p-type base regions 81 and face the bottoms of the trenches 84 in the depth direction.

The p⁺-type regions 501 and the p⁺-type regions 502 may formed concurrently and may have substantially the same dopant concentration. Further, the p⁺-type regions 501 and the p⁺-type regions 502 may be connected at a non-depicted location and may be electrically connected. In the fourth embodiment, across an entire area of the active region 21, the low carrier lifetime region 41 is provided at a depth position closer to the n⁺⁺-type drain region 1 than are the p⁺-type regions 501 and the p⁺-type regions 502 (in an instance in which the p⁺-type regions 501 and the p⁺-type regions 502 are omitted, the bottoms of the trenches 84).

As described above, according to the fourth embodiment, even when the trench gate structure is applied, effects similar to those of the first embodiment may be obtained.

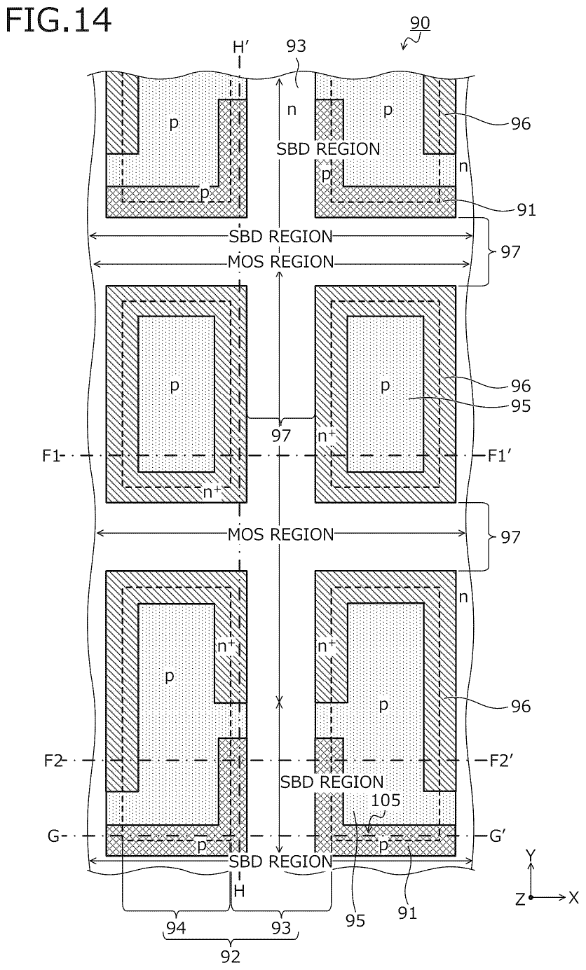

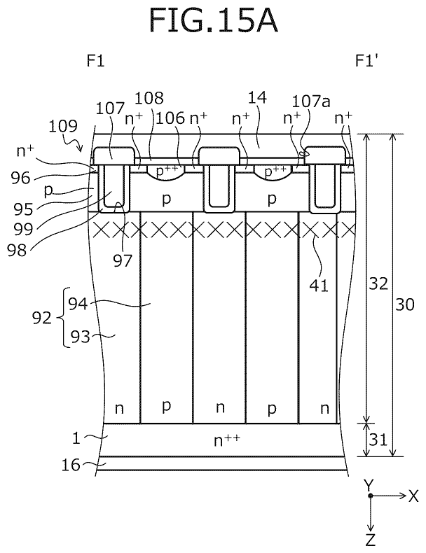

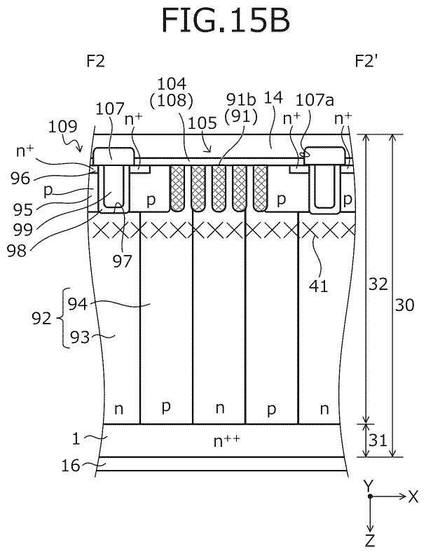

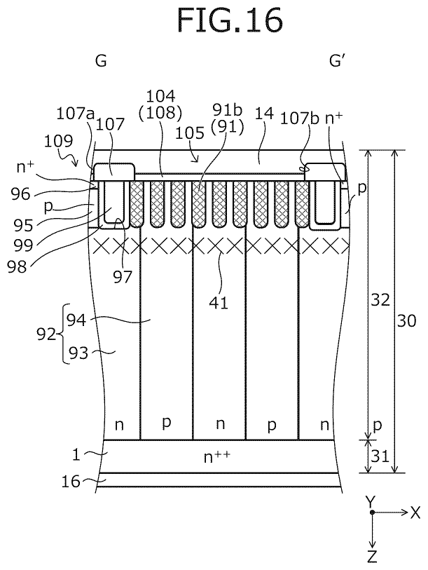

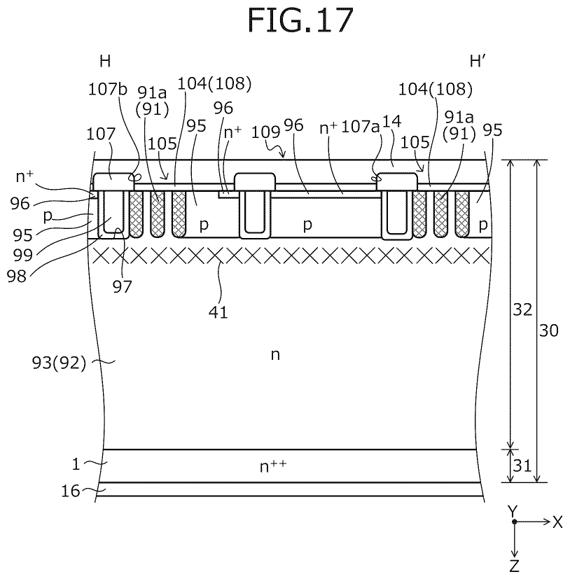

A structure of a semiconductor device according to a fifth embodiment is described. FIG. 14 is a plan view depicting a layout when a portion of the active region of the semiconductor device according to the fifth embodiment is viewed from the front surface of the semiconductor substrate. An overall layout when a semiconductor device 90 according to the fifth embodiment is viewed from the front surface of the semiconductor substrate 30 is the same as the layout in FIG. 1 except for a layout of MOS cells 109 and SBD cells of an SBD 105. In FIG. 13, multiple p-type regions 91 configuring the JBS structure of each of the SBD cells of the SBD 105 are collectively depicted as a single region (portions with lattice-pattern hatching). FIGS. 15A, 15B, 16, and 17 are cross-sectional views of the structure along cutting line F1-F1′, cutting line F2-F2′, cutting line G-G′, and cutting line H-H′ in FIG. 14, respectively.

The semiconductor device 90 according to the fifth embodiment differs from the semiconductor device according to the fourth embodiment (refer to FIG. 11) in that the MOS cells 109 and the SBD cells of the SBD 105 are disposed in a matrix-like pattern. In particular, the MOS cells 109 and the SBD cells of the SBD 105 each have a substantially rectangular shape of a same size in a plan view. The MOS cells 109 are disposed in a matrix-like pattern and partially sandwich the SBD cells of the SBD 105. In other words, in both the first and second directions X, Y, for every one or more of the MOS cells 109 disposed (disposed adjacently in an instance of two or more), one SBD cell of the SBD 105 is disposed adjacent to said MOS cells 109. Preferably, the SBD cells of the SBD 105 may be regularly interspersed. The MOS cells 109 and the SBD cells of the SBD 105 may be disposed in a checker-board-like pattern, adjacent to and repeatedly alternating with each other in both the first and second directions X, Y.

As for the MOS cells 109, in a plan view, a layout of n-type column regions 93 and p-type column regions 94 of a parallel pn layer 92 configuring the drift layer and in a plan view, a layout of p-type base regions 95, n⁺-type source regions 96, p⁺⁺-type contact regions 106, trenches 97, gate insulating films 98, and the gate electrodes 99 configuring the trench gate structure (in FIG. 14, the p⁺⁺-type contact regions 106 are not depicted) differ from the layout of the MOS cells 89 (in FIG. 1, replace reference number 9 with reference number 89) of the fourth embodiment. When viewed from the front surface of the semiconductor substrate 30, in the parallel pn layer 92, the p-type column regions 94 are disposed in a matrix-like pattern and the n-type column regions 93 are disposed in a grid-like pattern surrounding peripheries of the p-type column regions 94. A portion between centers of the gate electrodes 99 that are adjacent to each other constitutes one of the MOS cells 109. The MOS cells 109 are disposed in a same layout as the layout of the p-type column regions 94.

The p-type base regions 95 are provided in the MOS regions, in an entire area between the front surface of the semiconductor substrate 30 and the parallel pn layer 92. The n⁺-type source regions 96 and the p⁺⁺-type contact regions 106 are each selectively provided between the front surface of the semiconductor substrate 30 and the p-type base regions 95. The n⁺-type source regions 96 extend along the trenches 97 in a substantially rectangular shape or a U-shape. In the MOS regions, the trenches 97 penetrate through the n⁺-type source regions 96 and the p-type base regions 95 in the depth direction Z and reach the n-type column regions 93. From intersections of the n-type column regions 93 disposed in a grid-like pattern, the trenches 97 are provided extending along the n-type column regions 93 in the first and second directions X, Y in a cross-like shape or are provided extending along the n-type column regions 93 in a rectangular shape surrounding peripheries of the p-type base regions 95 or in a ladder-like shape. In the trenches 97, the gate electrodes 99 are provided via the gate insulating films 98.

The SBD 105 is a diode employing rectification of Schottky barriers formed at junction surfaces between the n-type column regions 93 that reach the front surface of the semiconductor substrate 30 and conductive films 104 in contact with said n-type column regions 93 at the front surface of the semiconductor substrate 30. In the first direction X (or in the second direction Y), a portion between centers of the gate electrodes 99 that are adjacent to each other and sandwich one of the Schottky junctions between the conductive films 104 and the n-type column regions 93 constitutes one SBD cell of the SBD 105. The SBD 105 may have a JBS structure in which both the Schottky junctions between the conductive films 104 and the n-type column regions 93, and pn junctions between the p-type regions 91 and the n-type column regions 93 are present. The p-type regions 91 configuring the JBS structure of the SBD cells are disposed in a grid-like pattern so as to form an overall cross-like shape in a plan view.

In particular, the p-type regions 91 that extent in stripe-like shapes in the first direction X (first p-type regions 91a) and the p-type regions 91 that extend in stripe-like shapes in the second direction Y (second p-type regions 91b) are disposed so as to intersect in a cross-like shape. The first and second p-type regions 91a, 91b, respectively, extend linearly along the n-type column regions 93, which extend in the first and second directions X, Y. A width of a region in which the first and second p-type regions 91a, 91b are disposed may be wider than the width Wn of the n-type column regions 93. The p-type column regions 94 or the n-type column regions 93 directly beneath the first p-type regions 91a that are adjacent to each other and the second p-type regions 91b that are adjacent to each other extend between said first p-type regions 91a that are adjacent to each other and between said second p-type regions 91b that are adjacent to each other. The p-type regions 91 are disposed apart from the n⁺-type source regions 96. The p-type regions 91 may be in contact with the p-type base regions 95 (or also in contact with the p⁺⁺-type contact regions 106). The p-type regions 91 may be in contact with the trenches 97.

An interlayer insulating film 107 is provided in an entire area of the front surface of the semiconductor substrate 30 and covers the gate electrodes 99. In the interlayer insulating film 107, contact holes 107a are provided for each of the MOS cells 109 while contact holes 107b are provided for each of the SBD cells of the SBD 105. The contact holes 107a, 107b of the interlayer insulating film 107 have substantially rectangular shapes in a plan view, the contact holes 107a having an opening area that is smaller than the surface area of the MOS cells 109 and the contact holes 107b having an opening area that is smaller than the surface area of the SBD cells of the SBD 105. The contact holes 107a, 107b are disposed in a matrix-like pattern so that the interlayer insulating film 107 remains in a grid-like pattern. A barrier metal 108 is provided in an entire area of the front surface of the semiconductor substrate 30, in the contact holes 107a, 107b. Configuration of the barrier metal 108 is a same as the configuration of the barrier metal 88 of the fourth embodiment (refer to FIG. 11). The conductive films 104 are constituted by the barrier metal 108 in the contact holes 107b.

The JBS structure of the SBD 63 of the semiconductor device 60 according to the second embodiment (refer to FIG. 4) may be applied to the SBD 105 of the semiconductor device 90 according to the fifth embodiment and the first and second p-type regions 91a, 91b of the SBD 105 may be interspersed in the first and second directions X, Y, respectively.

As described above, according to the fifth embodiment, even in an instance in which the cells are disposed in a matrix-like pattern, effects similar to those of the fourth embodiment may be obtained.

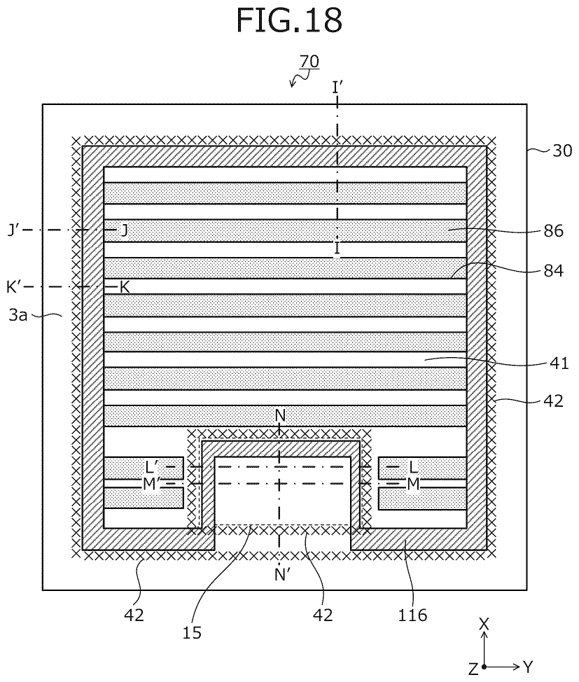

A structure of the edge termination region 22 is described as a structure of a semiconductor device according to a sixth embodiment. FIG. 18 is a plan view depicting a layout when the semiconductor device according to the sixth embodiment is viewed from the front surface of the semiconductor substrate. FIG. 19 is a plan view depicting another example of the layout when the semiconductor device according to the sixth embodiment is viewed from the front surface of the semiconductor substrate. FIGS. 18 and 19 depict layouts of the parallel pn layers 2 and 92 as viewed from the front surface of the semiconductor substrate 30, using the semiconductor devices 80 and 90 (FIGS. 11 to 16) described above as examples, respectively. FIGS. 18 and 19 are the same as FIG. 1, but with the addition of a layout of the trenches 84 and a gate polysilicon wiring layer 116.

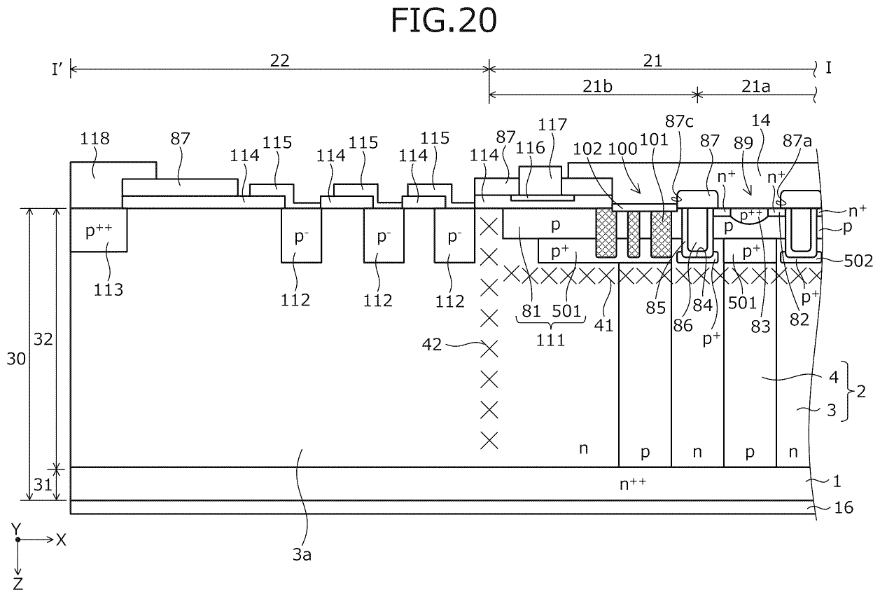

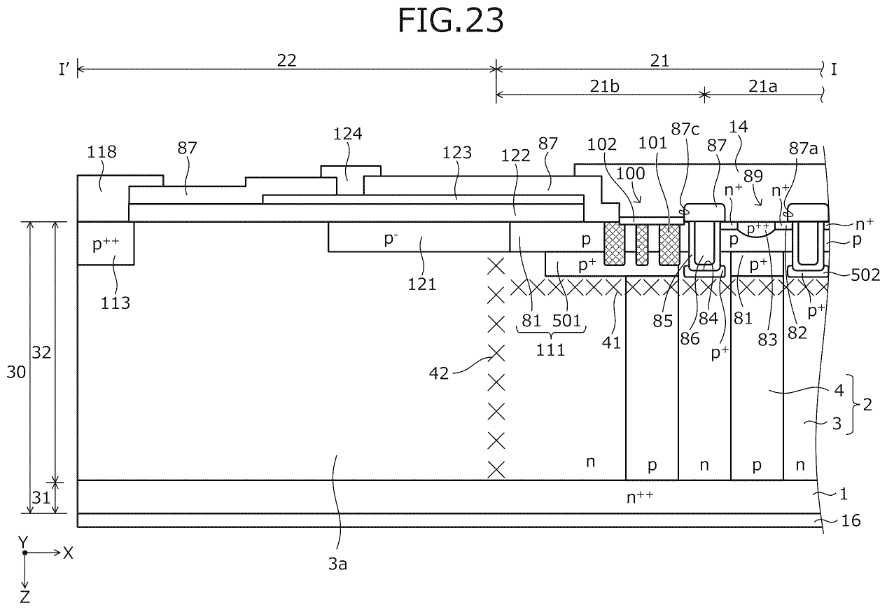

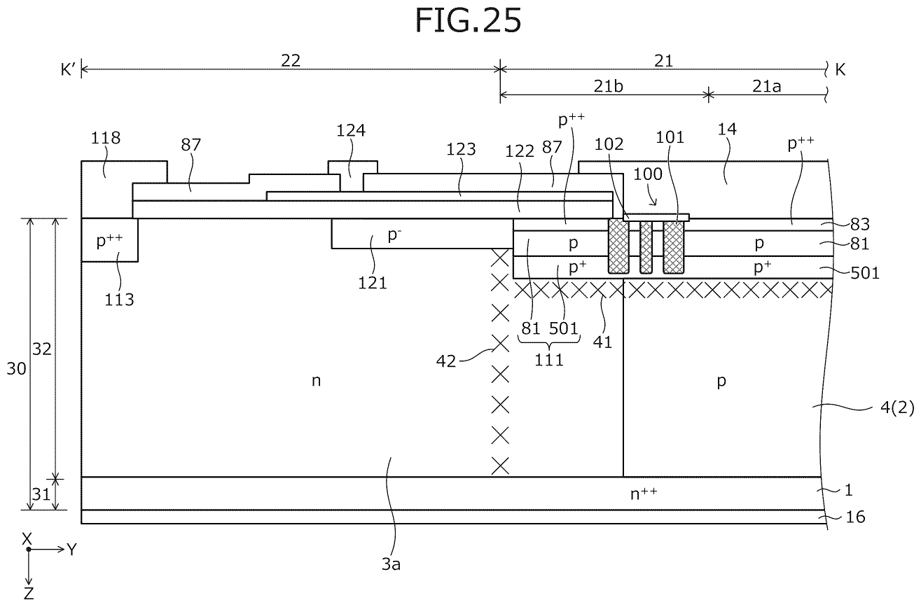

FIGS. 20, 21, and 22 are cross-sectional views of the structure along cutting line I-I′, cutting line J-J′, and cutting line K-K′ in FIG. 18, respectively. FIGS. 23, 24, and 25 are cross-sectional views of another example of the structure along cutting line I-I′, cutting line J-J′, and cutting line K-K′ in FIG. 18. The structure along cutting line I-I′, cutting line J-J′, and cutting line K-K′ in FIG. 19 is the same as that in which reference numbers 2 to 4 in FIGS. 20 to 25 are replaced with reference numbers 92 to 94. Herein, while the semiconductor devices 80, 90 of the fourth and fifth embodiments above are described as examples, the structure of the edge termination region 22 depicted in FIGS. 20 to 25 may be further applied to the semiconductor devices 10, 60, 70 according to the first to third embodiments above (FIGS. 1 to 10).

As depicted in FIGS. 18, and 20 to 22, in the semiconductor device 80 according to the fourth embodiment, the MOS cells 89 are disposed adjacent to each other in a center portion 21a of the active region 21. The center portion 21a of the active region 21 is a region that is closer to the chip center than is the center of a later-described outermost one of the gate electrodes 86 closest to the chip end (the end of the semiconductor substrate 30) in the first direction X and closer to the chip center than is a longitudinal end of the n⁺-type source regions 82 in the second direction Y. The drift layer in the outer peripheral portion 21b of the active region 21 is configured by the parallel pn layer 2, which extends from the center portion 21a of the active region 21, and an n-type region 3a adjacent to a chip-end side of the parallel pn layer 2. An outermost region of the parallel pn layer 2 closest to the chip end in the first direction X is one of the p-type column regions 4.

The n-type region 3a is a region between the parallel pn layer 2 and the chip end and is exposed at a side surface of the chip end. The n-type region 3a is in contact with the n-type column regions 3 and the p-type column regions 4, surrounds the periphery of the parallel pn layer 2 in a plan view, and connects all the n-type column regions 3 to each other. In the outer peripheral portion 21b of the active region 21, the p-type base regions 81 are provided between the front surface of the semiconductor substrate 30 and the parallel pn layer 2 and the n-type region 3a, and an outermost one of the p⁺-type regions 501 provided closest to the chip end, at a side of the p-type base regions 81 facing the n⁺⁺-type drain region 1 extends toward the chip end. In the outer peripheral portion 21b of the active region 21, portions of the p-type base regions 81 and the p⁺-type regions 501 extending toward the chip end are collectively referred to as an outer peripheral p-type region 111. In a contact hole 87c of the interlayer insulating film 87, the outer peripheral p-type region 111 is in contact with the source electrode 14 and is fixed to the potential of the source electrode 14.

Holes (minority carriers) are stored in the n-type column regions 3 of the edge termination region 22 during forward conduction of the body diodes of SJ-MOSFET and the outer peripheral p-type region 111 has a function of pulling out the holes to the source electrode 14 during reverse recovery of the body diodes. Further, a dopant concentration of the outer peripheral p-type region 111 may be a same as the dopant concentration of the p-type base regions 81 and the p⁺-type regions 501 or higher. For example, the dopant concentration may be about 1.0×10¹⁷/cm³. Across an entire area of the outer peripheral portion 21b of the active region 21, the low carrier lifetime region 41 is provided adjacent to the outer peripheral p-type region 111, at a depth position directly beneath the outer peripheral p-type region 111.

The contact hole 87c is provided in the interlayer insulating film 87 in the outer peripheral portion 21b of the active region 21 and surrounds the periphery of the center portion 21a of the active region 21. In the contact hole 87c, a source contact of the source electrode 14 and the outer peripheral p-type region 111 is formed. In the outer peripheral portion 21b of the active region 21, the source contact of the source electrode 14 and the outer peripheral p-type region 111 is formed, whereby during reverse recovery of the body diodes of the SJ-MOSFET, the holes stored in the n-type column regions 3 of the edge termination region 22 become reverse recovery current and easily flow in the outer peripheral p-type region 111. Along a path of the hole current (the reverse recovery current of the body diodes), the low carrier lifetime region 41 is formed, whereby the hole current easily flows into a later-described SBD 100.

At a boundary between the edge termination region 22 and the active region 21, the low carrier lifetime region 42 is provided in the n-type region 3a, adjacent to an outer peripheral end of the outer peripheral p-type region 111. The low carrier lifetime region 42 reaches at least an interface between the n-type region 3a and the n⁺⁺-type drain region 1 in the depth direction Z, from the front surface of the semiconductor substrate 30. The low carrier lifetime region 42 may be formed by irradiation of light ions such as protons (H⁺) or helium (He). The irradiation of light ions for forming the low carrier lifetime region 41, for example, may be performed with an irradiation dose in a range of about 1×10¹¹/cm² to 1×10¹³/cm², an acceleration voltage in a range of about 100 keV to 2 MeV, and from the front surface or the back surface of the semiconductor substrate 30. Further, the low carrier lifetime region 42 may be formed from the front surface of the semiconductor substrate 30 to a depth reaching the back surface, by an electron beam using a metal mask and an irradiation dose of the electron beam suffices to be, for example, in a range of about 20 kGy to 500 kGy. The low carrier lifetime region 42 has a function of suppressing an inflow of the reverse recovery current of the body diodes of the SJ-MOSFET into the edge termination region 22 from the active region 21.

Further, in the contact hole 87c, the SBD 100 is provided at a position facing the p-type column regions 4 in the depth direction Z. The SBD 100 is a diode employing rectification of Schottky barriers formed at junction surfaces between conductive films 102 and p-type regions 101 (portion with lattice-pattern hatching). The p-type regions 101 are diffused regions formed in surface regions of the epitaxial layer 32 by ion implantation and thermal diffusion. At positions facing, in the depth direction Z, longitudinal ends of all the p-type column regions 4 and the outermost one of the p-type column regions 4 closest to the chip end in the first direction X, the p-type regions 101 are provided at a depth so as to not penetrate through the outer peripheral p-type region 111 from the front surface of the semiconductor substrate 30. The p-type regions 101 have upper surfaces in contact with the conductive films 102 and peripheries of the p-type regions 101 are surrounded by the outer peripheral p-type region 111. The outer peripheral p-type region 111 intervenes between the p-type regions 101 that are adjacent to each other.

The p-type regions 101, for example, may concentrically surround the periphery of the center portion 21a of the active region 21 in a plan view so as to be partially interrupted at positions facing the n-type column regions 3 in the depth direction Z. The p-type regions 101 may face, in the depth direction Z, the n-type region 3a and/or the n-type column regions 3 that are adjacent to the p-type column regions 4 that face the p-type regions 101 in the depth direction Z. The SBD 100 is provided in the contact hole 87c, whereby holes stored in the n-type column regions 3 of the edge termination region 22 during reverse recovery of the body diodes is easily pulled out to the source electrode 14. As a result, minority carriers (holes) in the n-type column regions 3 of the edge termination region 22 decrease; in the edge termination region 22, recombination of carriers near the pn junctions between the p-type column regions 4 and the n-type column regions 3 is suppressed; and changes in the reverse recovery current of the body diodes of the SJ-MOSFET become gradual (soft recovery).

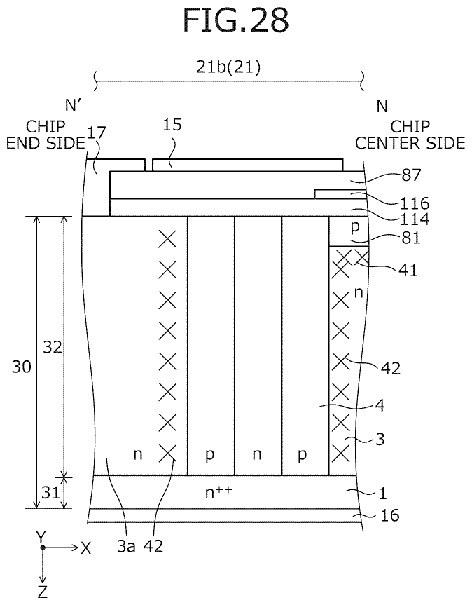

In the outer peripheral portion 21b of the active region 21 and the edge termination region 22, an insulating layer 114 and the interlayer insulating film 87 are sequentially stacked in the order stated on the front surface of the semiconductor substrate 30. The insulating layer 114 is formed by sequentially stacking in the order stated the gate insulating films 85, which extend from the center portion 21a of the active region 21 and a field oxide film. In the outer peripheral portion 21b of the active region 21, a gate polysilicon (poly-Si) wiring layer 116 is provided in the insulating layer 114. The gate polysilicon wiring layer 116 surrounds the periphery of the active region 21 in a substantially rectangular shape or U-shape. The gate polysilicon wiring layer 116 is connected to the gate electrodes 86 of all the MOS cells 89. A gate metal wiring layer 117 is in contact with the gate polysilicon wiring layer 116 through a contact hole that penetrates through the interlayer insulating film 87 and the insulating layer 114 in the depth direction Z. The gate metal wiring layer 117 surrounds the periphery of the active region 21 so as to be apart from a source wiring layer (refer to FIG. 28). The gate metal wiring layer 117 is connected to the gate pad 15 (refer to FIG. 1). The gate polysilicon wiring layer 116 and the gate metal wiring layer 117 configure the gate finger.

In the edge termination region 22, as a voltage withstanding structure, a FLR structure is provided between the front surface of the semiconductor substrate 30 and the n-type region 3a, closer to the chip end than is the low carrier lifetime region 42. The FLR structure is a structure in which multiple FLRs 112 that are floating p-type regions that are disposed apart from each other in concentric shapes surrounding the periphery of the active region 21. An innermost one of the FLRs 112 closest to the chip center may be adjacent to the low carrier lifetime region 42. A dopant concentration of the FLRs 112 is in a range of, for example, about 1.0×10¹⁴/cm³ to 1.0×10¹⁵/cm³. For example, the FLR structure is provided in an opening of the interlayer insulating film 87 and in the opening of the interlayer insulating film 87, multiple contact holes that expose, respectively, the different FLRs 112 are provided in the insulating layer 114. In the contact holes of the insulating layer 114, field plates (FPs) 115, which are floating metal electrodes in contact with the FLRs 112, respectively, are provided. The FPs 115 may extend on the insulating layer 114 from inside the contact hole.

In an outermost periphery of the edge termination region 22, between the front surface of the semiconductor substrate 30 and the n-type region 3a, a p⁺⁺-type channel stopper region 113 is provided apart from the FLR structure. The p⁺⁺-type channel stopper region 113 is exposed at the chip end. The p⁺⁺-type channel stopper region 113 is provided along an outer periphery of the semiconductor substrate 30. A dopant concentration of the p⁺⁺-type channel stopper region 113 is in a range of, for example, about 1.0×10¹⁸/cm³ to 1.0×10¹⁹/cm³. Instead of the p⁺⁺-type channel stopper region 113, an n⁺⁺-type channel stopper region may be provided. In the outermost periphery of the edge termination region 22, a channel stopper electrode 118 is provided on the front surface of the semiconductor substrate 30. The channel stopper electrode 118 is provided along the outer periphery of the semiconductor substrate 30. The channel stopper electrode 118 is in contact with the p⁺⁺-type channel stopper region 113 via a contact hole that penetrates through the interlayer insulating film 87 and the insulating layer 114 in the depth direction Z.

As depicted in FIGS. 23 to 25, instead of the FLR structure, a JTE structure 121 may be provided as a voltage withstanding structure. The JTE structure 121 is a structure in which multiple p⁻-type regions with differing dopant concentrations are disposed adjacently in concentric shapes surrounding the periphery of the active region 21 so as to be arranged in descending order of dopant concentration in a direction from the chip center to the chip end. In FIGS. 23 to 25, the multiple p⁻-type regions configuring the JTE structure 121 are depicted as a single p⁻-type region. An innermost end (innermost one of the p⁻-type regions closest to the chip center) of the JTE structure 121 is in contact with the outer peripheral p-type region 111 and fixed to the potential of the source electrode 14 via the outer peripheral p-type region 111. In an instance in which the voltage withstanding structure is the JTE structure 121, the depth position of the low carrier lifetime region 42 and arrangement of the gate finger (a gate polysilicon wiring layer 123 and gate metal wiring layer 124) are different from the structure depicted in FIGS. 20 to 22.

The low carrier lifetime region 42 reaches at least the interface between the n-type region 3a and the n⁺⁺-type drain region 1 from an interface between the JTE structure 121 and the n-type region 3a. The FPs 115 are omitted and in the edge termination region 22, an entire area of the front surface of the semiconductor substrate 30 is covered by an insulating layer 122 and the interlayer insulating film 87. Configuration of the insulating layer 122 is the same as the configuration of the insulating layer 114 in FIGS. 20 to 22. The gate polysilicon wiring layer 123 is provided having a width extending closer to the chip end than is the JTE structure 121, from the outer peripheral portion 21b of the active region 21 and covers the entire periphery of the JTE structure 121 via the insulating layer 122. The gate metal wiring layer 124, for example, is connected to the gate polysilicon wiring layer 123 in the depth direction Z, at a position facing an outer peripheral end (the innermost one of the p⁻-type regions closest to the chip center) of the JTE structure 121, in the depth direction Z, via a contact hole that penetrates through the interlayer insulating film 87 and the insulating layer 122.

In the outer peripheral portion 21b of the active region 21 of the semiconductor device 90 according to the fifth embodiment depicted in FIG. 19, arrangement of the n-type column regions 93 and the p-type column regions 94 of the parallel pn layer 92 differs from the arrangement in the semiconductor device 70 according to the fourth embodiment depicted in FIG. 18. In particular, in the semiconductor device 90 according to the fifth embodiment, the outer peripheral portion (portion in contact with an inner end of an n-type region 93a that surrounds a periphery of the parallel pn layer 92) of the parallel pn layer 92 is disposed with the n-type column regions 93 and the p-type column regions 94 adjacent to and repeatedly alternating with each other over the entire periphery. Thus, in the contact hole 87c of the interlayer insulating film 87 in the outer peripheral portion 21b of the active region 21, the SBD 100 is provided interspersed along the outer periphery of the parallel pn layer 92.

As described above, according to the sixth embodiment, application to the semiconductor device according to the first to fifth embodiments is possible.

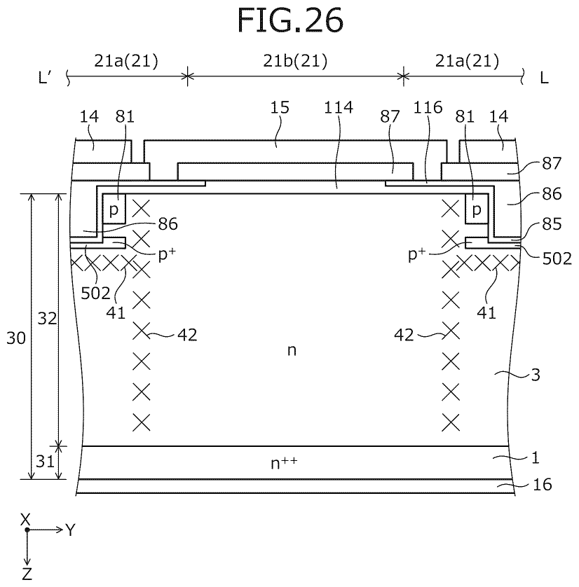

The structure directly beneath the gate pad 15 of the structure of the semiconductor device according to the sixth embodiment depicted in FIG. 18 is described as a structure of a semiconductor device according to a seventh embodiment. FIGS. 26, 27, and 28 are cross-sectional views of the structure along cutting line L-L′, cutting line M-M′, and cutting line N-N′ in FIG. 18. Herein, while the semiconductor device according to the sixth embodiment above (i.e., the semiconductor device 80 according to the fourth embodiment depicted in FIGS. 11 to 13) is described as an example, the structure directly beneath the gate pad 15 depicted in FIGS. 26 to 28 may be further applied to the semiconductor devices 10, 60, 70, 90 according to the first, third, and fifth embodiments above (FIGS. 1 to 10, 13 to 16, and 18).

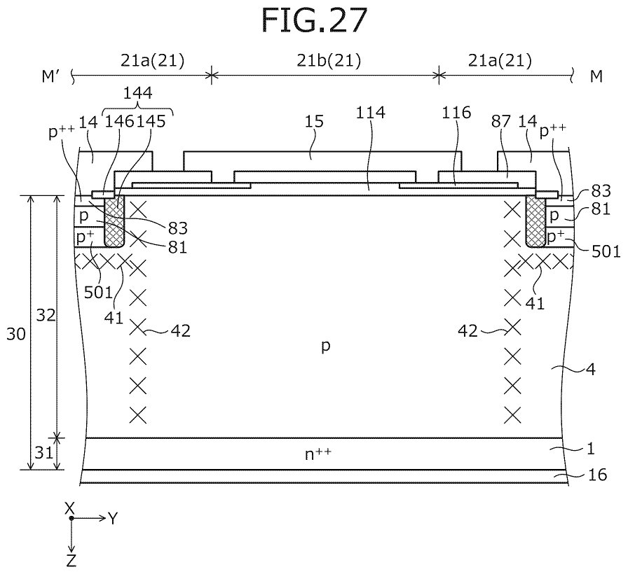

As depicted in FIGS. 26 to 28, in the outer peripheral portion 21b of the active region 21, the gate pad 15 is provided on the front surface of the semiconductor substrate 30 via the insulating layer 114 and the interlayer insulating film 87. The gate polysilicon wiring layer 116 is provided so as to face the outer periphery of the gate pad 15 in the depth direction Z, via the interlayer insulating film 87 directly beneath the gate pad 15. The drift layer directly beneath the gate pad 15 suffices to be configured by the parallel pn layer 2 and to be configured by the n-type region 3a. Directly beneath the gate pad 15, the p-type base regions 81 may be omitted and the front surface of the semiconductor substrate 30 may coincide with the parallel pn layer 2 or the n-type region 3a. FIG. 27 is a cross-sectional view (along cutting line M-M′) at one of the p-type column regions 4 of the semiconductor device according to the seventh embodiment depicted in FIG. 18. In the semiconductor device according to the seventh embodiment, in the semiconductor substrate 30, JBS structures 144 formed by conductive films 146 and p-type regions 145 in contact with the front surface of the semiconductor substrate 30 may be selectively provided so as to surround the outer periphery of the gate pad 15.

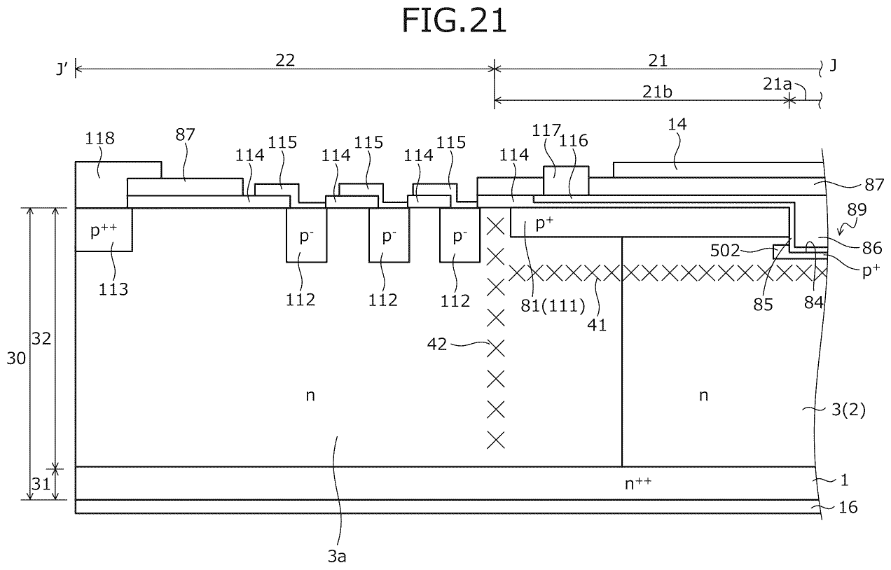

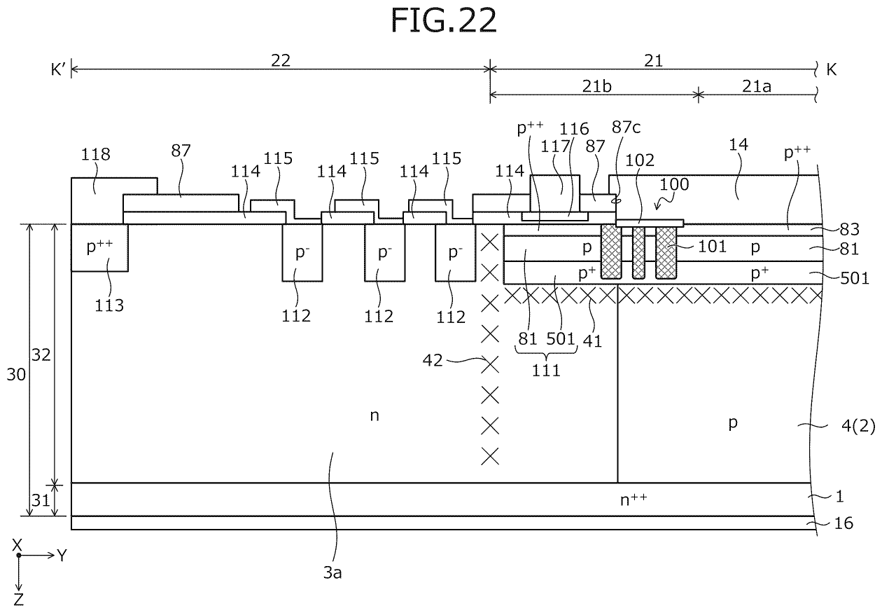

A source wiring layer 17 is provided closer to the chip end than are the gate pad 15 and the gate metal wiring layer 117 (refer to FIGS. 21 and 22 (FIG. 28). Through a contact hole of the interlayer insulating film 87, the source wiring layer 17 is in contact with the outer peripheral p-type region 111 and the outer peripheral p-type region 111 is fixed to the potential of the source electrode 14. Across an entire area of the outer peripheral portion 21b of the active region 21, the low carrier lifetime region 41 is provided adjacent to the outer peripheral p-type region 111, at a position directly beneath the outer peripheral p-type region 111.

The low carrier lifetime region 42 is provided in the parallel pn layer 2 and in the n-type region 3a and faces the outer periphery of the gate pad 15 in the depth direction Z. In an instance in which the p-type base regions 81 directly beneath the gate pad 15 are omitted, the low carrier lifetime region 42 suffices to be provided directly beneath ends of the p-type base regions 81. The low carrier lifetime region 42 may be provided directly beneath an end of the gate polysilicon wiring layer 116 disposed at the periphery of the gate pad 15.

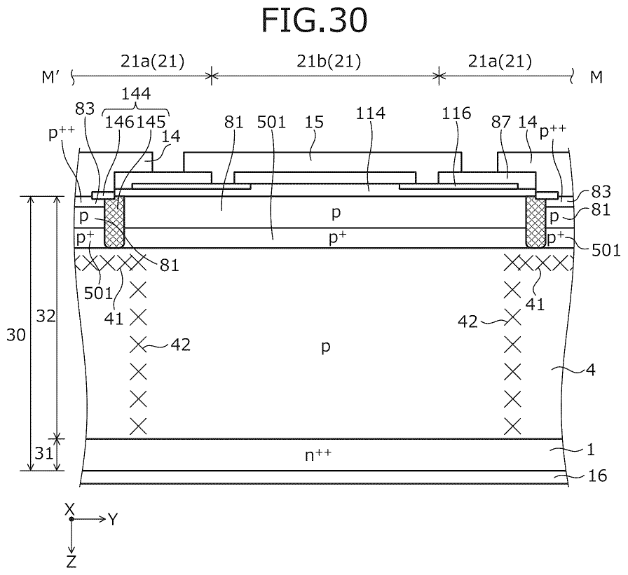

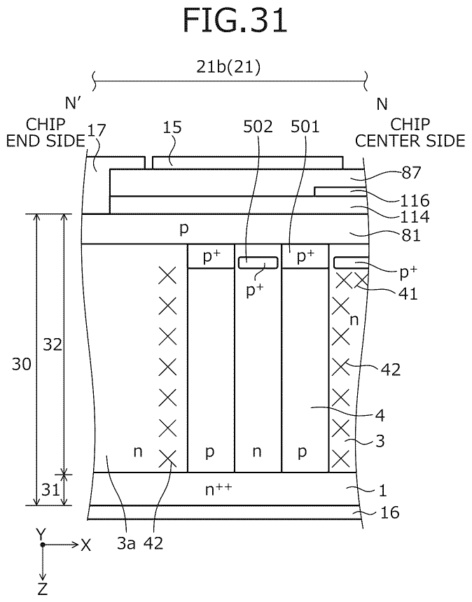

FIGS. 29, 30, and 31 depict another example of a semiconductor device according to the seventh embodiment. In the semiconductor device depicted in FIGS. 29 to 31, the p-type base regions 81 provided directly beneath the gate pad 15, between the front surface of the semiconductor substrate 30 and the parallel pn layer 2 and the n-type region 3a is different from the semiconductor device depicted in FIGS. 26 to 28 while other portions of the structure are the same as those of the semiconductor device depicted in FIGS. 26 to 28. In the semiconductor device depicted in FIGS. 29 to 31, the p-type regions 145, which are in contact with the front surface of the semiconductor substrate 30, and the JBS structures 144 formed by the conductive films 146 are selectively provided in the semiconductor substrate 30 so as to surround the outer periphery of the gate pad 15 in a plan view. The n⁺-type source regions 82 and the p⁺⁺-type contact regions 83 may be omitted in a portion closer to and beneath the gate pad 15 than are the JBS structures 144.

As described above, according to the seventh embodiment, application to the semiconductor devices according to the first to sixth embodiments is possible.

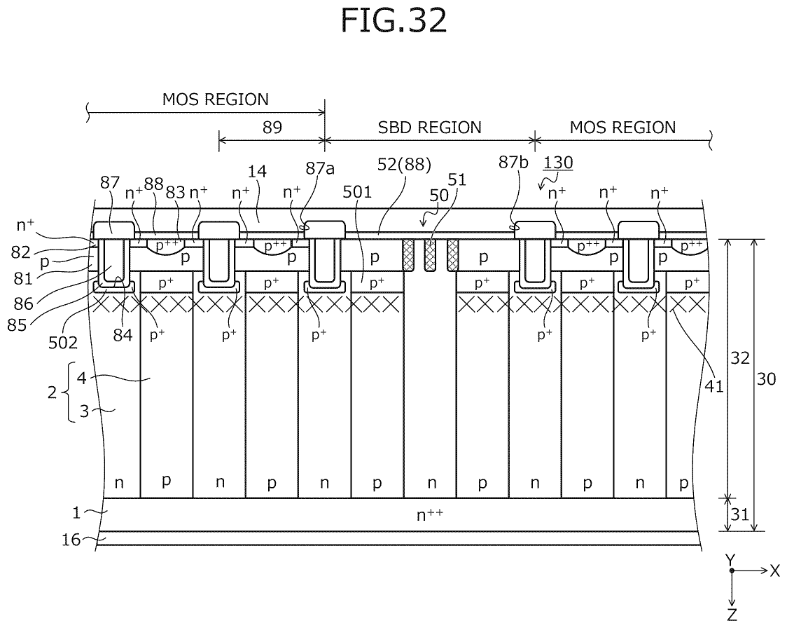

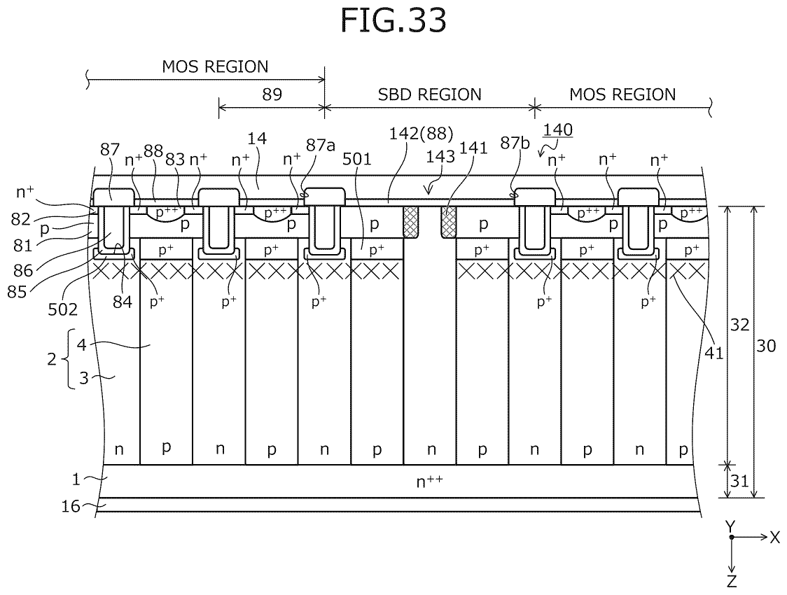

A structure of a semiconductor device according to an eighth embodiment is described. FIG. 32 is a cross-sectional view depicting the structure of the semiconductor device according to the eighth embodiment. FIG. 33 is a cross-sectional view depicting another example of the structure of the semiconductor device according to the eighth embodiment. A semiconductor device 130 according to the eighth embodiment depicted in FIG. 32 differs from the semiconductor device 10 according to the first embodiment (refer to FIG. 3) in that the low carrier lifetime region 41 is not provided directly below the SBD 50. The low carrier lifetime region 41 is not provided directly below the SBD 50, whereby the resistance of the SBD 50 decreases and reverse recovery current easily flows in the SBD 50 during reverse recovery of the body diodes of the SJ-MOSFET.

A semiconductor device 140 according to the eighth embodiment depicted in FIG. 33 differs from the semiconductor device 130 according to the eighth embodiment depicted in FIG. 32 in that a SBD 143 has a merged pin/Schottky (MPS) structure that employs rectification of Schottky barriers formed by conductive films 142, the n-type column regions 3, and the n⁺⁺-type drain region 1. In an instance of the SBD 143 having the MPS structure, between the p-type base regions 81 that are adjacent to each other, two p-type regions 141 are provided in contact with said p-type base regions 81, respectively. The n-type column region 3 extends between the adjacent p-type regions 141 and reaches the front surface of the semiconductor substrate 30.

The semiconductor device 130 according to the eighth embodiment depicted in FIG. 32 or the semiconductor device 140 according to the eighth embodiment depicted in FIG. 33 may be applied to the semiconductor devices 60, 70, 80, 90 according to the second to fifth embodiments and configuration may be such that the low carrier lifetime region 41 of the second to fifth embodiments is not provided directly beneath the SBDs 63, 66, 50, 105 of the second to fifth embodiments, and the SBD 63, 66, 50, 105 of the second to fifth embodiments may have the MPS structure. Selection of whether the SBDs 63, 66, 50, 105 are to have the JBS structure or the MPS structure is based on cell pitch, the width Wn of each of the n-type column regions 3, and the dopant concentration of the p-type base regions 81.

As described above, according to the eighth embodiment, effects similar to those of the first to sixth embodiments may be obtained.

In the foregoing, the present invention is not limited to the embodiments above and various modifications within a range not departing from the spirit of the invention are possible. For example, the present invention is further applicable to Si semiconductor devices that use silicon (Si) as a semiconductor material and have a breakdown voltage of about, for example, 600V or less. Further, in the embodiments, while a first conductivity type is assumed to be an n-type and a second conductivity type is assumed to be a p, the present invention is similarly implemented when the first conductivity type is a p-type and the second conductivity type is an n-type.

According to the invention described above, changes in the reverse recovery current of the parasitic pn junction diodes (body diodes) formed by the insulated gate structure in the semiconductor substrate may be made gradual. Further, the amount of effective (apparent) reverse recovery current of the body diodes may be reduced.

The semiconductor device according to the present invention achieves an effect in that reverse recovery characteristics of the body diodes may be improved.

As described, the semiconductor device according to the present invention is useful for power semiconductor devices used in power converting equipment, power source devices used in various types of industrial machines and is particular suitable for SJ-MOSFETs employing, as a semiconductor material, SiC which has a high breakdown voltage (for example, 3.3 kV or greater) and a large chip side.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device, comprising:
a semiconductor substrate having an active region and a termination region that surrounds a periphery of the active region in a plan view of the semiconductor device, the semiconductor substrate further having a first main surface and a second main surface opposite to each other;
a parallel pn layer formed in the semiconductor substrate, the parallel pn layer including a plurality of first-conductivity-type column regions of a first conductivity type and a plurality of second-conductivity-type column regions of a second conductivity that are disposed in the active region and repeatedly alternating with each other in a first direction that is parallel to the first main surface of the semiconductor substrate;
a plurality of first semiconductor regions of the second conductivity type, selectively provided in the semiconductor substrate and in contact with the parallel pn layer;
a plurality of second semiconductor regions of the first conductivity type, selectively provided in the semiconductor substrate, at the first main surface thereof, each of the plurality of second semiconductor regions being in contact with one of the plurality of first semiconductor regions;
a plurality of gate insulating films selectively provided at the first main surface of the semiconductor substrate, in the active region;
a plurality of gate electrodes respectively provided at positions facing the semiconductor substrate across the plurality of gate insulating films, in the active region;
a first electrode provided at the first main surface of the semiconductor substrate, in contact with the plurality of second semiconductor regions;
a second electrode provided at the second main surface of the semiconductor substrate; and
a plurality of conductive films selectively provided between the first main surface of the semiconductor substrate and the first electrode, each of the plurality of conductive films being in contact with the first electrode and the plurality of first-conductivity-type column regions, wherein
the plurality of conductive films and the plurality of first-conductivity-type column regions form a plurality of Schottky junctions therebetween, configuring a Schottky barrier diode; and
the parallel pn layer has a first low carrier lifetime region, in which a first carrier lifetime killer is introduced, formed at depth positions respectively directly beneath the plurality of first semiconductor regions, across an entire area of the active region.

2. The semiconductor device according to claim 1, further comprising
a second low carrier lifetime region, in which a second carrier lifetime killer is introduced, provided from an upper surface of the semiconductor substrate to a lower surface of the parallel pn layer, at a boundary between the active region and the termination region.

3. The semiconductor device according to claim 1, further comprising:
a gate pad provided at the first main surface of the semiconductor substrate, apart from the first electrode, the gate pad being electrically connected to the plurality of gate electrodes; and
a second low carrier lifetime region in which a second carrier lifetime killer is introduced, provided from an upper surface of the parallel pn layer to a lower surface of the parallel pn layer, directly beneath an outer periphery of the gate pad.

4. The semiconductor device according to claim 1, further comprising
a plurality of third semiconductor regions of the second conductivity type, selectively provided between the plurality of conductive films and the plurality of first-conductivity-type column regions, the plurality of third semiconductor regions being in contact with the plurality of conductive films, wherein
the Schottky barrier diode has a junction barrier Schottky (JBS) structure in which the plurality of Schottky junctions between the plurality of conductive films and the plurality of first-conductivity-type column regions, and a plurality of pn junctions between the plurality of third semiconductor regions and the plurality of first-conductivity-type column regions are both present.

5. The semiconductor device according to claim 4, wherein a lower end of each of the plurality of third semiconductor regions is at a same depth as a lower surface of each of the plurality of first semiconductor regions, or is closer to the first main surface of the semiconductor substrate than is the lower surface of each of the plurality of first semiconductor regions.

6. The semiconductor device according to claim 4, wherein a dopant concentration of the plurality of third semiconductor regions is same as or higher than a dopant concentration of the plurality of first semiconductor regions.

7. The semiconductor device according to claim 1, further comprising
a first-conductivity-type high-concentration region provided between the second main surface of the semiconductor substrate and the parallel pn layer, the first-conductivity-type high-concentration region being in contact with the second electrode and having a dopant concentration higher than a dopant concentration of the plurality of first-conductivity-type column regions, wherein
the Schottky barrier diode has a merged pin Schottky (MPS) structure configured by the plurality of Schottky junctions between the plurality of conductive films and the plurality of first-conductivity-type column regions, and the first-conductivity-type high-concentration region.

8. The semiconductor device according to claim 1, wherein the plurality of gate electrodes, the plurality of gate insulating films, the plurality of first semiconductor regions, and the plurality of second semiconductor regions configure an insulated gate structure, the insulated gate structure having a plurality of cells disposed in the first direction, partially sandwiching a plurality of cells of the Schottky barrier diode, each of the plurality of cells of the insulated gate structure extending in a stripe-like shape in a second direction that is parallel to the first main surface of the semiconductor substrate and orthogonal to the first direction.

9. The semiconductor device according to claim 1, wherein the plurality of gate electrodes, the plurality of gate insulating films, the plurality of first semiconductor regions, and the plurality of second semiconductor regions configure an insulated gate structure, the insulated gate structure having a plurality of cells disposed in a matrix-like pattern, partially sandwiching a plurality of cells of the Schottky barrier diode.

10. The semiconductor device according to claim 1, wherein the plurality of gate electrodes, the plurality of gate insulating films, the plurality of first semiconductor regions, and the plurality of second semiconductor regions configure an insulated gate structure that is a planar gate structure in which the plurality of gate electrodes extends along the first main surface of the semiconductor substrate.

11. The semiconductor device according to claim 1, wherein the plurality of gate electrodes, the plurality of gate insulating films, the plurality of first semiconductor regions, and the plurality of second semiconductor regions configure an insulated gate structure that is a trench gate structure in which the plurality of gate electrodes extends in a depth direction from the first main surface of the semiconductor substrate.

12. The semiconductor device according to claim 1, wherein
the first carrier lifetime killer is helium or protons, and
the first low carrier lifetime region is formed with an irradiation dose of the first carrier lifetime killer in a range of 1×10¹¹/cm² to 1×10¹³/cm².

13. The semiconductor device according to claim 2, wherein
the second carrier lifetime killer is helium or protons, and
the second low carrier lifetime region is formed with an irradiation dose of the second carrier lifetime killer in a range of 1×10¹¹/cm² to 1×10¹³/cm².

14. The semiconductor device according to claim 3, wherein
the second carrier lifetime killer is helium or protons, and
the second low carrier lifetime region is formed with an irradiation dose of the second carrier lifetime killer in a range of 1×10¹¹/cm² to 1×10¹³/cm².

15. The semiconductor device according to claim 2, wherein
the second carrier lifetime killer is provided by electron beam irradiation, and
an irradiation dose of the second carrier lifetime killer is at least 20 kGy but less than 500 kGy.

16. The semiconductor device according to claim 3, wherein
the second carrier lifetime killer is provided by electron beam irradiation, and
an irradiation dose of the second carrier lifetime killer is at least 20 kGy but less than 500 kGy.

17. The semiconductor device according to claim 1, wherein
the first conductivity type is an n-type, and
a material of the conductive film is molybdenum.
